(19) United States
(12) Patent Application Publication
(10) Pub. No.: US 2023/0197703 A1
(43) Pub. Date: Jun. 22, 2023

(54) DIRECT-CURRENT-DRIVABLE FULL-COLOR LIGHT-EMITTING DIODE DISPLAY AND METHOD OF MANUFACTURING THE SAME

(71) Applicant: Kookmin University Industry Academy Cooperation Foundation, Seoul (KR)

(72) Inventor: Young Rag DO, Seoul (KR)

(73) Assignee: Kookmin University Industry Academy Cooperation Foundation, Seoul (KR)

(21) Appl. No.: 18/083,303

(22) Filed: Dec. 16, 2022

(30) Foreign Application Priority Data
Dec. 17, 2021 (KR) 10-2021-0181878

(51) Int. Cl. H01L 25/16; H01L 33/62; H01L 33/20; H01L 33/50

(52) U.S. Cl. CPC H01L 25/167; H01L 33/62; H01L 33/20; H01L 33/507; H01L 33/32

(57) ABSTRACT

The present disclosure relates to a full-color light-emitting diode (LED) display, and more particularly, to a full-color LED display that may be driven by direct current (DC) and a method of manufacturing the same.

### CROSS-REFERENCE TO RELATED APPLICATION

This application claims priority to and the benefit of Korean Patent Application No. 2021-0181878, filed on Dec. 17, 2021, the disclosure of which is incorporated herein by reference in its entirety.

### BACKGROUND

### 1. Field of the Invention

The present disclosure relates to a full-color light-emitting diode (LED) display, and more particularly, to a direct-current-drivable full-color LED display and a method of manufacturing the same.

### 2. Discussion of Related Art

Micro-light-emitting diodes (Micro-LEDs) and nano-LEDs may implement an excellent feeling of color and high efficiency and may be eco-friendly materials, and thus are used as core materials for displays. In line with such market conditions, recently, research for developing shell-coated nano-cable LEDs through new nanorod LED structures or new manufacturing processes is being conducted. In addition, research on a protective film material is being conducted to achieve high efficiency and high stability of a protective film covering an outer surface of nanorods, or research and development of a ligand material advantageous for a subsequent process is also being conducted.

Further, in line with research in such material fields, research on a mounting technology for mounting independent individual micro-LEDs and nano-LEDs on electrodes having a nano- or micro-unit size is also being actively conducted because it is practically impossible to mount micro-LEDs and nano LEDs one by one on target portions on the electrodes with a pick-and-place technology.

As part of these studies, Korean Patent Publication No. 10-1436123 discloses a display manufactured through a method of dropping a solution mixed with nanorod-type LEDs on sub-pixels, and then self-aligning nanorod-type LED elements on electrodes by forming an electric field between two aligned electrodes to form the sub-pixels.

However, the disclosed technology has a technical limitation in that the LED elements may be driven only by applying alternating current (AC) power to two electrodes because one end, which is an n-type semiconductor side, and the other end, which is a p-type semiconductor side, of the rod-type LED element in a major-axis direction are inevitably aligned randomly on two different electrodes on the same plane.

Further, a rod-type LED element has a structure in which two different semiconductor layers and a photoactive layer are stacked in a major-axis direction, and since the disclosed technology is a technology in which the rod-type LED element having such a structure is inevitably mounted while lying on the horizontal electrodes, which are horizontally spaced apart from each other, in the major-axis direction, rather than being mounted upright in the major-axis direction on the electrodes, a display that emits light more strongly to a side surface than a front surface is inevitably manufactured, and thus it is difficult to implement a display having sufficient front luminance.

Accordingly, there is an urgent need to develop an LED material and LED alignment technology that can greatly improve front luminance of a display implemented by aligning LED elements on electrodes in a direction in which layers constituting the LED element are stacked, and can implement an LED display that can be driven by direct current (DC) by controlling and aligning two semiconductor layers so that a direction in which two different semiconductor layers are aligned on electrodes is in any one direction.

### SUMMARY OF THE INVENTION

The present disclosure is directed to providing a method of manufacturing a direct-current-drivable light-emitting diode (LED) electrode assembly capable of improving front luminance and light emission efficiency by solving the conventional problems of side light emission even for a display implemented by self-aligning nano- or micro-scale LED elements, capable of easily arranging electrodes for addresses when implementing sub-pixels of the display, and capable of implementing a display that can be driven even with a DC power source by easily controlling a mounting direction of the LED elements, and a direct-current-drivable LED electrode manufactured through the same.

One aspect of the present disclosure provides a direct-current-drivable full-color light-emitting diode (LED) display, including a lower electrode line part including one or more first electrodes and having a plurality of sub-pixel sites formed on main surfaces of the first electrodes, an alignment guide part configured to cover at least a main surface portion of each of the first electrodes corresponding to each of the sub-pixel sites and including two or more holes each passing through a portion corresponding to each of the sub-pixel sites so as to have a first shape, a plurality of LED structures, each of which emits light of substantially the same color, includes a first conductive semiconductor layer, a photoactive layer, and a second conductive semiconductor layer, which are stacked in a first direction, and includes a first face and a second face facing each other in the first direction, wherein a shape of the second face and a shape of the first face, which is the first shape, are congruent with each other, but the shape of the first face and the shape of the second face have an asymmetric shape in which a symmetrical axis does not exist, and a second face side end portion of each of the LED structures is inserted into the hole of the alignment guide part such that the second face of each of the LED structures is brought into contact with the main surface of each of the first electrodes, and aligned on the first electrode, an upper electrode line part including one or more second electrodes disposed on the plurality of aligned LED structures, and a color conversion part patterned on main surfaces of the second electrodes corresponding to the sub-pixel sites so that the sub-pixel sites respectively become sub-pixel sites each expressing any one of a blue color, a green color, and a red color.

Another aspect of the present disclosure provides a direct-current-drivable full-color light-emitting diode (LED) display, including a lower electrode line part including one or more first electrodes and having a plurality of sub-pixel sites formed on main surfaces of the first electrodes, an alignment guide part configured to cover at least a main surface portion of each of the first electrodes corresponding to each of the sub-pixel sites and including two or more holes each passing through a portion corresponding to each of the sub-pixel sites so as to have a first shape, a plurality of LED structures, each of which includes a first conductive semiconductor layer, a photoactive layer, and a second conductive semiconductor layer, which are stacked in a first direction, includes a first face and a second face facing each other in the first direction, and includes a blue LED structure, a green LED structure, and a red LED structure, each of which has a shape in which a shape of the second face and a shape of the first face, which is the first shape, are congruent with each other but the shape of the first face and the shape of the second face have an asymmetric shape in which a symmetrical axis does not exist, wherein each of the LED structures is disposed in each of the sub-pixel sites so as to have substantially the same color of light, a second face side end portion of each of the LED structures is inserted into the hole of the alignment guide part such that the second face of each of the LED structures is brought into contact with the main surface of each of the first electrodes and aligned on the first electrode, and an upper electrode line part including one or more second electrodes disposed on the plurality of aligned LED structures.

According to one embodiment of the present disclosure, a shape of each of the remaining faces of the LED structure except for the first face and the second face may be different from the shape of at least one of the first face and the second face.

Further, each of the first face and the second face may have an area of 0.20 μm² to 100 μm².

Further, a thickness that is a vertical distance between the first face and the second face may be in a range of 0.3 μm to 3.5 μm.

Further, the first conductive semiconductor layer may be an n-type Group III-nitride semiconductor layer, and an electron delay layer may be further included below the first conductive semiconductor layer so that the number of electrons and the number of holes recombined in the photoactive layer are balanced.

Further, the electron delay layer may include, for example, at least one selected from the group consisting of CdS, GaS, ZnS, CdSe, CaSe, ZnSe, CdTe, GaTe, SiC, ZnO, ZnMgO, SnO₂, TiO₂, In₂O₃, Ga₂O₃, Si, poly(paraphenylene vinylene), derivatives thereof, polyaniline, poly(3-alkylthiophene), and poly(paraphenylene).

Further, when the first conductive semiconductor layer may be a doped n-type Group III-nitride semiconductor layer, and the electron delay layer may be a III-nitride semiconductor having a doping concentration lower than that of the first conductive semiconductor layer.

Further, the full-color LED display may further include a protective film configured to cover the remaining face of the LED structure except for the first face and the second face.

Further, the first conductive semiconductor layer may be an n-type Group III-nitride semiconductor layer, the second conductive semiconductor layer may be a p-type Group III-nitride semiconductor layer, and the full-color LED display may further include at least one functional film of a hole pushing film configured to cover exposed side surfaces of the second conductive semiconductor layer, or the exposed side surfaces of the second conductive semiconductor layer and exposed side surfaces of at least a portion of the photoactive layer, and move holes on the exposed side surface toward a center, and an electron pushing film configured to cover exposed side surfaces of the first conductive semiconductor layer and move electrons on the exposed side surface toward a center.

Further, in the lower electrode line part, a plurality of first electrodes may be formed to be spaced apart from each other by a predetermined interval in a main surface direction, each of the sub-pixel sites may be formed on at least two adjacent first electrodes, each of the LED structures may be a rod-type LED structure elongated in a second direction perpendicular to the first direction with an aspect ratio of a major axis and a minor axis of 2:1 or more in each of the first face and the second face, the hole may pass through the alignment guide part such that a portion of the hole corresponds to the main surface of one of the two adjacent first electrodes and a portion of the remaining portion of the hole corresponds to the main surface of the remaining first electrode, so that a front-end second face portion and a rear-end second surface portion of the rod-type LED structure are respectively disposed on the main surfaces of the two adjacent first electrodes, and the second face side end portion of each of the plurality of LED structures may be inserted into the hole of the alignment guide part and aligned on the first electrode.

Further, the LED structure may further include at least one of a second electrode layer provided on the first conductive semiconductor layer and a first electrode layer provided on the second conductive semiconductor layer.

Further, the light color is blue, white, or ultraviolet (UV).

Still another aspect of the present disclosure provides a method of manufacturing a direct-current-drivable full-color light-emitting diode (LED) display, including operation (1) of preparing a lower electrode line part including one or more first electrodes and having a plurality of sub-pixel sites formed on main surfaces of the first electrodes, operation (2) of forming an alignment guide part, which is configured to cover at least a main surface portion of each of the first electrodes corresponding to each of the sub-pixel sites and includes two or more holes each passing through a portion corresponding to each of the sub-pixel sites so as to have a first shape, on the lower electrode line part, operation (3) of printing an ink composition for a printing apparatus, which includes a plurality of LED structures, each of which emits light of substantially the same color, includes a first conductive semiconductor layer, a photoactive layer, and a second conductive semiconductor layer, which are stacked in a first direction, and includes a first face and a second face facing each other in the first direction, wherein a shape of the second face and a shape of the first face, which is the first shape, are congruent with each other, but the shape of the first face and the shape of the second face have an asymmetric shape in which a symmetrical axis does not exist, on a region of the alignment guide part corresponding to each of the sub-pixel sites, operation (4) of aligning the plurality of LED structures on the main surfaces of the first electrodes by inserting a second face side end portion of each of the LED structures placed on the alignment guide part into the hole of the alignment guide part, operation (5) of forming an upper electrode line part including one or more second electrodes on the plurality of aligned LED structures so as to be in contact with the first face of the LED structure, and operation (6) of patterning a color conversion part on the second electrode corresponding to the sub-pixel site so that the sub-pixel sites become sub-pixel sites each expressing any one of a blue color, a green color, and a red color in each of the plurality of sub-pixel sites.

Yet another aspect of the present disclosure provides a method of manufacturing a method of manufacturing a direct-current-drivable full-color light-emitting diode (LED) display, including operation (I) of preparing a lower electrode line part including one or more first electrodes and having a plurality of sub-pixel sites formed on main surfaces of the first electrodes, operation (II) of forming an alignment guide part, which is configured to cover at least a main surface portion of each of the first electrodes corresponding to each of the sub-pixel sites and includes two or more holes each passing through a portion corresponding to each of the sub-pixel sites so as to have a first shape, on the lower electrode line part, operation (III) printing a blue LED structure ink composition, a green LED structure ink composition, and a red LED structure ink composition each including a plurality of LED structures for each light color, each of which includes a first conductive semiconductor layer, a photoactive layer, and a second conductive semiconductor layer, which are stacked in a first direction, and includes a first face and a second face facing each other in the first direction, wherein a shape of the second face and a shape of the first face, which is the first shape, are congruent with each other, but the shape of the first face and the shape of the second face have an asymmetric shape in which a symmetrical axis does not exist, and the ink compositions are printed on a region of the alignment guide part corresponding to each of the sub-pixel sites so that each of the plurality of sub-pixel sites independently expresses any one color, operation (IV) of aligning the plurality of LED structures by inserting a second face side end portion of each of the LED structures placed on the alignment guide part into the hole of the alignment guide part, and operation (V) of forming an upper electrode line part including one or more second electrodes on the plurality of aligned LED structures so as to be in contact with the first face of the LED structure.

Further, an area of the hole provided in the alignment guide part may be formed to be 1.01 to 1.50 times larger than an area of the second face of each of the LED structures.

Further, the hole may be formed in a portion of the alignment guide part corresponding to the main surface of the first electrode.

Further, a partition wall configured to surround the sub-pixel site with a predetermined thickness may be further formed on the alignment guide part corresponding to each of the sub-pixel sites.

Further, each of the LED structures may be a rod-type LED structure elongated in a second direction perpendicular to the first direction with an aspect ratio of a major axis and a minor axis of 2:1 or more in each of the first face and the second face, in the lower electrode line part, a plurality of first electrodes may be formed to be spaced apart from each other by a predetermined interval in a main surface direction, each of the sub-pixel sites may be formed on at least two adjacent first electrodes, the hole may pass through the alignment guide part such that a portion of the hole corresponds to the main surface of one of the two adjacent first electrodes and a portion of the remaining portion of the hole corresponds to the main surface of the remaining first electrode, so that a front-end second face portion and a rear-end second surface portion of the rod-type LED structure are respectively disposed on the main surfaces of the two adjacent first electrodes, and the second face side end portion of each of the plurality of LED structures may be inserted into the hole of the alignment guide part and aligned on the first electrode.

Further, the aligning of the plurality of LED structures may include a process of radiating a sound wave one time or multiple times.

Further, a linker for chemical bonding may be provided on any one or more of the second face of the LED structure, an inner surface of the hole, and a bottom surface of the hole, so that each of the plurality of LED structures aligned by being inserted into the hole is not separated from the hole.

Further, the method may further include, after the plurality of LED structures are aligned on the first electrode, heat-treating for improving electrical contact between the second face of the LED structure and the first electrode, and depositing an insulating material to fill a space between each LED structure and the hole into which the LED structure is inserted and to planarize a space between the plurality of aligned LED structures.

Hereinafter, terms used in the present disclosure are defined.

In descriptions of embodiments of the present disclosure, it should be understood that when, a layer, region, or pattern is referred to as being “on,” “above,” “under,” or “below” a substrate, another layer, another region, or another pattern, the terminology of “on,” “above,” “under,” or “below” includes both the meanings of “directly” and “indirectly” “on,” “above,” “under,” or “below.”

On the other hand, it is informed that the present invention has been researched with the support of the following national R&D projects.

[National Research and Development Project 1 Supporting This Invention]

[Project Series Number] 1711130702

[Project Number]2021R1A2C2009521

[Government Department Name] Ministry of Science and ICT

[Project Management Authority Name] Korea Evaluation Institute of Industrial Technology

[Research Program Name] Middle-level Researcher Support Project

[Research Project Name] Development of dot-LED Material and Display Source/Application Technology

[Contribution Ratio] 1/2

[Project Execution Organization Name] Kookmin University Industry Academic Cooperation Foundation

[Period Of Research] Mar. 1, 2021 to Feb. 28, 2022

[National Research and Development Project 2 Supporting This Invention]

[Project Series Number] 1415174040

[Project Number] 20016290

[Government Department Name] Ministry of Trade, Industry and Energy

[Project Management Authority Name] Korea Evaluation Institute of Industrial Technology

[Research Program Name] Electronic Components Industry Technology Development-Super Large Micro-LED Modular Display

[Research Project Name] Development of sub-micron blue light-emitting source technology for modular display

[Contribution Ratio] 1/2

[Project Execution Organization Name] Kookmin University Industry Academic Cooperation Foundation

[Period Of Research] Apr. 1, 2021 to Dec. 31, 2024

### BRIEF DESCRIPTION OF THE DRAWINGS

The above and other objects, features, and advantages of the present disclosure will become more apparent to those of ordinary skill in the art by describing exemplary embodiments thereof in detail with reference to the accompanying drawings, in which:

FIG. 1 is a schematic plan view of a full-color light-emitting diode (LED) according to a first embodiment of the present disclosure;

FIG. 2 is a schematic cross-sectional view taken along line X-X′ of FIG. 1;

FIG. 3(a)-3(f) is a schematic view illustrating a manufacturing process of the full-color LED display according to the first embodiment of the present disclosure;

FIG. 4 is a schematic plan view of a full-color LED display according to a second embodiment of the present disclosure;

FIG. 5 is a schematic cross-sectional view taken along line Y-Y′ of FIG. 4;

FIG. 6(a)-6(f) is a schematic view illustrating a manufacturing process of the full-color LED display according to the second embodiment of the present disclosure;

FIG. 7 is a perspective view of an LED structure having an asymmetric face used in one embodiment of the present disclosure;

FIG. 8 is a plan view illustrating a first face (A) and a second face (B) of the LED structure in a first direction according to FIG. 7;

FIGS. 9A to 9D are plan views each illustrating a first face (A) and a second face (B) of each of the LED structures, which have various shapes, in the first direction, wherein FIG. 9A is a view illustrating an example of the first face (A) and the second face (B) without having a symmetrical axis, and FIGS. 9B to 9D are views illustrating an example of the first face (A) and the second face (B) having one or more symmetrical axes;

FIG. 10 is a cross-sectional view of an LED structure used in one embodiment of the present disclosure;

FIG. 11 is a cross-sectional view of an LED structure used in one embodiment of the present disclosure;

FIGS. 12 and 13(a)-13(c) are schematic views illustrating a mechanism in which an alignment surface and an alignment direction of an LED structure are controlled through an alignment guide part during a manufacturing process of a full-color LED display according to one embodiment of the present disclosure;

FIG. 14 is a schematic view corresponding to a comparative example of the present disclosure, and illustrates a possible alignment aspect when an LED structure having a symmetrical surface is inserted and aligned using an alignment guide part;

FIG. 15(a)-15(h) is a schematic process view illustrating a portion of a manufacturing process of manufacturing a full-color LED display according to one embodiment of the present disclosure;

FIG. 16(a)-16(d) is a schematic view illustrating a process of applying a bonding force between an LED structure and a lower electrode through a chemical bonding linker as one method to prevent separation of the LED structure during a process of manufacturing a full-color LED display according to one embodiment of the present disclosure;

FIG. 17 is a schematic cross-sectional view of a full-color LED display according to one embodiment of the present disclosure;

FIG. 18(a)-18(b) is a schematic view illustrating a process of mounting an LED structure using an electric field during a process of manufacturing the full-color LED display according to FIG. 17; and

FIG. 19 is a plan view of one surface of an LED structure in the first direction, which is suitable for a manufacturing process of the full-color LED display shown in FIG. 17 and the full-color LED display shown in FIG. 18(a)-18(b).

### DETAILED DESCRIPTION OF EXEMPLARY EMBODIMENTS

Hereinafter, embodiments of the present disclosure will be described in detail with reference to the drawings such that those skilled in the art to which the present disclosure can easily carry out the present disclosure. The present disclosure may be implemented in several different forms, and are not limited to the embodiments described herein.

First, as a display according to a first embodiment of the present disclosure, a full-color light-emitting diode (LED) display implemented with LED elements emitting light of substantially the same color will be described.

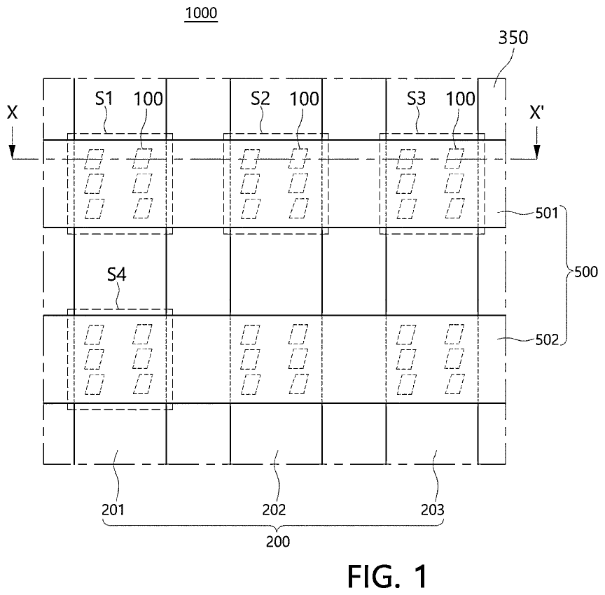

Referring to FIGS. 1 to 3(a)-3(f), 7, and 8, a full-color LED display 1000 according to the first embodiment of the present disclosure may be implemented by including a lower electrode line part 200 including one or a plurality of first electrodes 201, 202, and 203 and having a plurality of sub-pixel sites S₁, S₂, S₃, and S₄ formed on main surfaces of the first electrodes 201, 202, and 203, an alignment guide part 300 that covers at least a main surface portion of each of the first electrodes 201, 202, and 203 corresponding to each of the sub-pixel sites S₁, S₂, S₃, and S₄ and includes at least two holes H each passing through a portion corresponding to each of the sub-pixel sites S₁, S₂, S₃, and S₄ so as to have a first shape, a plurality of LED structures 100, which are aligned on the first electrodes 201, 202, and 203 as an end portion of a second face B thereof is inserted into the hole H of the alignment guide part 300 such that the second face B is in contact with the main surface of the first electrode 201, 202, or 203, an upper electrode line part 500 including one or a plurality of second electrodes 501 and 502 disposed on the plurality of aligned LED structures 100, and a color conversion part 700 patterned on main surfaces of the second electrodes corresponding to the sub-pixel sites S₁, S₂, S₃, and S₄ so that the sub-pixel sites S₁, S₂, S₃, and S₄ become sub-pixel sites each expressing any one of blue, green, and red colors.

First, the lower electrode line part 200 and the upper electrode line part 500 that allow the LED structures 100 to emit light will be described before describing each component in detail.

The display 1000 according to the first embodiment of the present disclosure includes the upper electrode line part 500 and the lower electrode line part 200 disposed above and below the LED structures 100 to face each other with the LED structures 100 therebetween. Since the upper electrode line part 500 and the lower electrode line part 200 are not arranged in a horizontal direction, electrodes may be very simply designed and may be implemented more easily by breaking away from a complicated electrode line of a conventional display by electric field induction, in which two types of electrodes implemented to have ultra-small thicknesses and widths are arranged to have micro- or nano-scale spacing in the horizontal direction in a plane of a limited area. In addition, since thin-film transistors (TFTs) are also easily arranged, in addition to active matrix driving, passive matrix driving, which is X-Y matrix driving, is also possible, and thus various types of displays can be implemented much more easily.

Further, the lower electrode line part 200 and the upper electrode line part 500 may include one or the plurality of first electrodes 201, 202, and 203 and one or the plurality of second electrodes 501 and 502, respectively, and the number, interval, arrangement shape, and the like thereof may be appropriately modified in consideration of the area, luminance, and the like of the display to be implemented, and thus, the present disclosure is not particularly limited thereto.

Further, when the upper electrode line part 500 is designed to be in electrical contact with an upper portion of the LED structure 100 mounted on the lower electrode line part 200, for example, first surfaces A, there is no limitation on the number, arrangement shape, and the like of the upper electrode line part 500. However, as shown in FIG. 1, when the first electrodes 201, 202, and 203 of the lower electrode line part 200 are arranged in parallel in one direction, the second electrodes 501 and 502 of the upper electrode line part 500 may be arranged to be perpendicular to the one direction, and such an electrode arrangement is an electrode arrangement widely used in a conventional display and the like, and thus there is an advantage in that the electrode arrangement and control technology of the conventional display field may be used as it is.

Further, the first electrodes 201, 202, and 203 constituting the lower electrode line part 200 and the second electrodes 501 and 502 constituting the upper electrode line part 500 may each have a material, a shape, a width, and a thickness of an electrode used for a display employing a typical LED, and may be manufactured using a known method, and thus the present disclosure is not particularly limited thereto. As an example, the first electrodes 201, 202, and 203 and the second electrodes 501 and 502 may each independently include aluminum, chromium, gold, silver, copper, graphene, indium tin oxide (ITO), or alloys thereof, and may have a width of 2 μm to 50 μm and a thickness of 0.1 μm to 100 μm, which may be appropriately changed in consideration of the size and the like of the desired LED display.

According to one embodiment of the present disclosure, the plurality of sub-pixel sites S₁, S₂, S₃, and S₄ may be formed on the first electrodes 201, 202, and 203. The sub-pixel sites S₁, S₂, S₃, and S₄ refer to virtual regions configured to partition main surfaces of the first electrodes 201, 202, and 203. In addition, each of the sub-pixel sites S₁, S₂, S₃, and S₄ may be a minimum unit for implementing a color. As an example, although LEDs emitting light of substantially the same color are disposed in each of the sub-pixel sites S₁, S₂, S₃, and S₄, since the color conversion part 700, which is excited by the emitted light to express different types of light colors, is patterned on each of the sub-pixel sites S₁, S₂, S₃, and S₄, each of the sub-pixel sites S₁, S₂, S₃, and S₄ may eventually implement any one color.

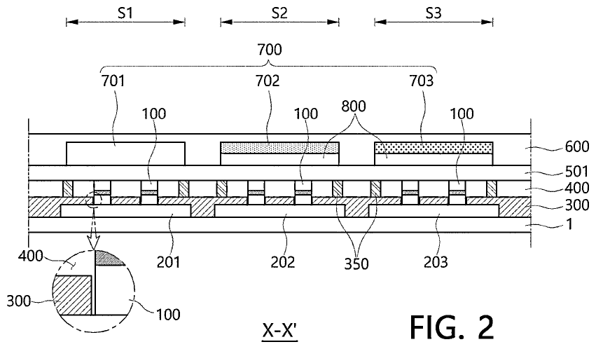

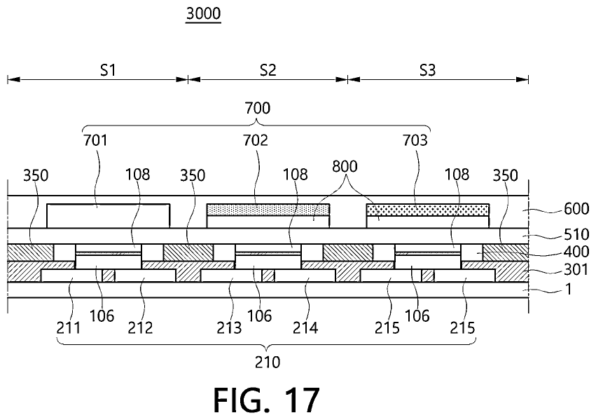

Further, the sub-pixel sites S₁, S₂, S₃, and S₄ may be variously set according to the purpose. As an example, as shown in FIGS. 1 and 2, the sub-pixel sites S₁, S₂, S₃, and S₄ may be set to be spaced apart from each other by a predetermined interval, for example, by an interval between the adjacent first electrodes 201, 202, and 203, or, as shown in FIG. 17, the sub-pixel sites S₁, S₂, and S₃ may be set adjacent to each other with one common partition wall 350 therebetween, but the present disclosure is not limited thereto, and the sub-pixel sites may be formed without being spaced apart from each other.

Further, the sub-pixel sites S₁, S₂, S₃, and S₄ are formed on the main surfaces of the first electrodes 201, 202, and 203, and as shown in FIG. 1, one sub-pixel site may be formed on the main surface of any one first electrode 201, 202, or 203. Alternatively, one sub-pixel site may be formed on the main surfaces of the two or more first electrodes adjacent to each other, and as an example, one sub-pixel site may be formed on the main surfaces of two adjacent first electrodes 211/212, 213/214, or 215/216 as shown in FIG. 17.

Further, each of the sub-pixel sites S₁, S₂, S₃, and S₄ may have a unit area of 100 μm×100 μm or less, 30 μm×30 μm or less as another example, and 20 μm×20 μm or less as still another example, and the unit area of such a size is an area reduced compared to a unit sub-pixel area of a display using an LED, and thus at least two LED structures are disposed in one sub-pixel site S₁, S₂, S₃, or S₄ while minimizing an area ratio occupied by the LED structures, which may be advantageous for realizing a large-area and high-resolution display. In addition, since each of the plurality of sub-pixel sites S₁, S₂, S₃, and S₄ is disposed to include at least two LED structures to be described below, even when a defective LED structure is included among the LED structures disposed in each of the sub-pixel sites S₁, S₂, S₃, and S₄, a predetermined light can be emitted from all of the sub-pixel sites S₁, S₂, S₃, and S₄ unless all the LED structures provided in each of the sub-pixel sites S₁, S₂, S₃, and S₄ are defective, thereby minimizing or preventing the occurrence of defective pixels in the display. In addition, the unit area of each of the sub-pixel sites S₁, S₂, S₃, and S₄ may be different from each other.

Further, a separate surface treatment may be performed or a groove may be formed on uppermost surfaces of the sub-pixel sites S₁, S₂, S₃, and S₄. In addition, although the arrangement of electrodes such as a data electrode, a gate electrode, and the like provided in a typical display is not illustrated in FIG. 1, the arrangement of the electrodes used in the typical display may be employed for the arrangement of the electrodes not illustrated in the drawing.

Next, the alignment guide part 300, which covers at least a main surface portion of each of the first electrodes 201, 202, and 203 corresponding to each of the sub-pixel sites S₁, S₂, S₃, and S₄ and includes at least two holes H each passing through a portion thereof corresponding to each of the sub-pixel sites S₁, S₂, S₃, and S₄ so as to have the first shape, will be described.

The alignment guide part 300 is a member for controlling an alignment surface and an alignment direction of each of the plurality of LED structures 100 mounted on the first electrodes 201, 202, and 203 by making the shape of the provided hole H to be the same as the shape of the first face A of the LED structure 100 to be described below and accommodating only a second face side end portion of the LED structure 100 in the hole H.

The alignment guide part 300 may be provided to cover a desired region for mounting the LED structure 100, in other words, to cover at least a main surface portion of each of the first electrodes 201, 202, and 203 corresponding to each of the sub-pixel sites S₁, S₂, S₃, and S₄, and may be further formed in a region other than each of the sub-pixel sites S₁, S₂, S₃, and S₄.

Further, the alignment guide part 300 includes at least two holes H each passing therethrough so as to have the first shape that is the same as the shape of the first face A of the LED structure 100, and thus, at least two LED structures 100 can be provided in each of the sub-pixel sites S₁, S₂, S₃, and S₄.

Further, the hole H may be formed in a portion of the alignment guide part 300 corresponding to the main surface of each of the first electrodes 201, 202, and 203. That is, one end of the LED structure 100 inserted into the hole H can be electrically connected the first electrode 201, 202, or 203 only when a portion or all of the first electrode 201, 202, or 203 is exposed through the hole H. As an example, as shown in FIGS. 1 and 2, the hole H may be located in the main surface of any one first electrode 201, 202, or 203. Alternatively, as shown in FIG. 17, the hole H may be formed such that a portion of the hole H corresponds to the main surface of any one first 211, 213, or 215 among the two adjacent first electrodes 211/212, 213/214, or 215/216 and a portion of the remaining portion of the hole H corresponds to the main surface of the remaining first electrode 212, 214, or 216.

Further, the hole H may be formed to have a size 1.01 to 1.50 times larger than an area of the first face A of the LED structure 100 so that one end of the LED structure 100 in a first direction is easily inserted into the hole H. When the hole H is formed to have a size less than 1.01 times the area of the first face A, one end of the LED structure may be difficult to be inserted into the hole H, and thus, the time for performing a process of aligning the LED structures may be extended, or the LED structures may not be disposed in some holes H in the alignment guide part 300 despite the extended time of the alignment process. In addition, when the hole H is formed to have a size more than 1.50 times the area of the first face A, one end of the LED structure may be easily separated even when the one end of the LED structure is inserted and aligned in the hole H.

Further, the hole H may be formed to preferably have a depth 0.5 to 1.5 times a thickness of the LED structure so that the LED structure inserted into the hole H is not separated from the hole H, which may be advantageous in that the insertion and alignment of one end of the LED structure is not inhibited while preventing the inserted and aligned LED structure from being separated from the hole H.

Further, the alignment guide part 300 may be made of an insulating material so as not to affect the driving of the mounted LED structure, and may include, for example, at least one from among silicon nitride (Si₃N₄), silicon dioxide (SiO₂), aluminum oxide (Al₂O₃), hafnium oxide (HfO₂), zirconium oxide (ZrO₂), yttrium oxide (Y₂O₃), titanium dioxide (TiO₂), aluminum nitride (AlN), and gallium nitride (GaN). In addition, the alignment guide part 300 may have a thickness, for example, of 0.1 μm to 5.0 μm, and the thickness of the alignment guide part 300 is not limited thereto, and the thickness may be appropriately changed in consideration of the thickness of the prepared LED structure.

Further, on the alignment guide part 300 described above, the partition wall 350 surrounding the sub-pixel site S₁, S₂, S₃, or S₄ with a predetermined thickness may be further provided on a portion of the alignment guide part 300 corresponding to each of the sub-pixel sites S₁, S₂, S₃, and S₄. The partition wall 350 performs a function of preventing an ink composition, which includes the plurality of LED structures 100 and is discharged on the alignment guide part 300, from flowing out of each of the sub-pixel sites S₁, S₂, S₃, and S₄ to other sites in a display manufacturing process. The partition wall 350 may be formed of a sidewall having a predetermined width. In addition, as shown in FIG. 2, one partition wall 350 may be formed for each of the sub-pixel sites S₁, S₂, and S₃, or as illustrated in FIG. 17, the partition wall 350 may be formed such that the plurality of sub-pixel sites S₁, S₂, and S₃ share any one sidewall of the partition wall 350.

Further, the partition wall 350 may be made of an insulating material so as not to provide an electrical influence when the LED structure 100 is driven. Preferably, the insulating material may use any one or more from among inorganic insulating materials, silicon dioxide (SiO₂), silicon nitride (Si₃N₄), aluminum oxide (Al₂O₃), hafnium oxide (HfO₂), yttrium oxide (Y₂O₃), and titanium dioxide (TiO₂), and various transparent polymer insulating materials. In addition, the partition wall 350 may be manufactured as the partition wall 350 by forming an insulating material on the alignment guide part 300 to have a height of the partition wall 350 and then performing a patterning and etching process to have a sidewall shape surrounding the plurality of holes H of the alignment guide part 300. At this point, the height of the partition wall 350 is ½ or more of the thickness of the LED structure, and may be preferably in a range of 0.1 μm to 100 μm, and more preferably 0.3 to 10 μm as a thickness that may not normally affect post-processing. When the above-described range is not satisfied, which may affect a post process, and thus it may be difficult to manufacture an LED electrode assembly. In particular, when a thickness of the insulating material is too small compared to the thickness of the LED structure, the effect of preventing the spread of the LED structures through the partition wall may be insufficiently achieved, and there is a risk that the ink composition including the LED structures may overflow out of the partition wall.

Next, the LED structure 100, which is disposed between the lower electrode line part 200 and the upper electrode line part 500 described above and aligned as one end thereof is inserted into the hole H of the above-described alignment guide part 300, will be described.

The LED structures 100 emit light having substantially the same light color. Here, the term “substantially the same light color” does not refer to completely the same wavelength of emitted light and refers to light in a wavelength range in which light generally referred to as light having the same light color is included. As an example, when the light color is blue, the LED structure configured to emit light in a wavelength range of 420 nm to 470 nm may be understood as emitting light having substantially the same light color. The LED structure provided in the display according to the first embodiment of the present disclosure may emit, for example, blue light, white light, or ultraviolet (UV) light.

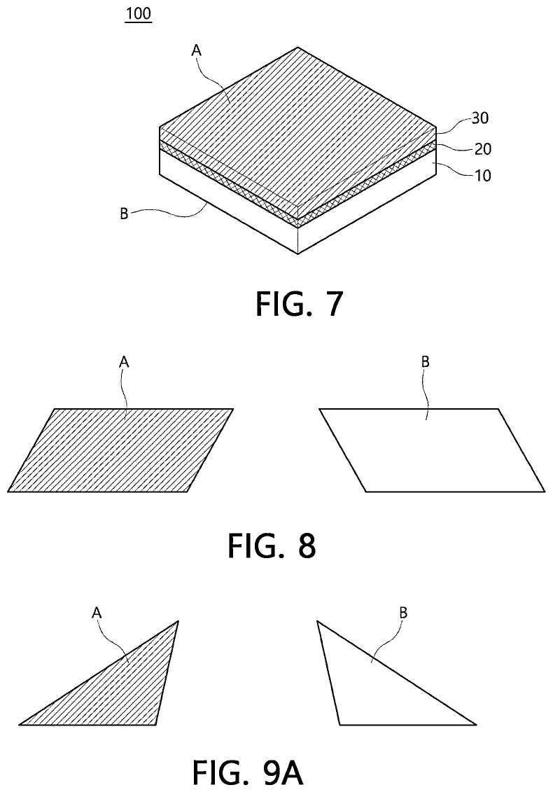

Further, when described with reference to FIGS. 7 and 8, the LED structure 100 employed in the display according to the present disclosure is a structure in which layers including a first conductive semiconductor layer 10, a photoactive layer 20, and a second conductive semiconductor layer 30 are stacked in the first direction. In addition, in the LED structure 100 according to the present disclosure, the first face A and the second face B facing each other in the first direction have a congruent shape, but have an asymmetric shape in which a symmetrical axis does not exist. Here, the first direction refers to a direction perpendicular to a main surface of each layer constituting the LED structure.

Further, the shape of each of the first face A and the second face B refers to a shape of the face exposed to the outside of the LED structure 100, that is, a shape of a corresponding face shown when viewing the LED structure 100, and does not refer to an inverted shape corresponding to a virtual rear face of a visible face (or an exposed face). Here, the term “a certain shape has the same shape as that of the first face A or the second face B” refers to a case in which the certain shape is identical to the shape (or the shape of the exposed face) of the first face A or the second face B as seen from the outside, that is, the certain shape is completely overlapped with the shape of the first face A or the second face when the certain shape is overlapped without inverting a front side and a back side thereof, and a case in which only an inverted surface is identical does not correspond to the case of the same shape.

Further, the term “congruence” refers to a case in which the sizes of the first face A and the second face B, which are flat surfaces, are equal to each other, and any one of the first face A and the second face B is completely overlapped with the other when the any one is overlapped with the other one as it is or by inverting front and back sides. Thus, in the present disclosure, the term “a certain shape is congruent with the shape of the first face A or the second face B” includes a case in which the certain shape is identical to the shape of the inverted surface and thus has a broader meaning compared to the case in which shapes of surfaces seen without inversion are identical to each other.

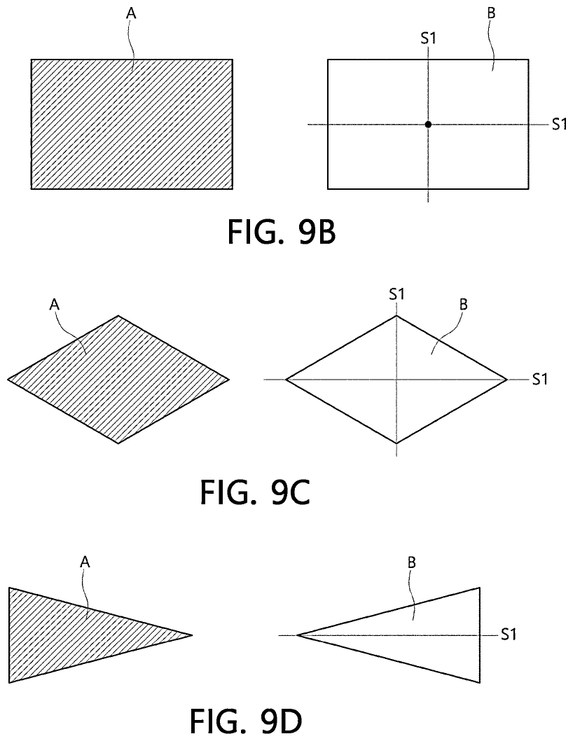

Further, the term “the first face A and the second face B are asymmetric faces having an asymmetric shape” refers to a surface in which a symmetrical axis does not exist, and here, the term “symmetrical axis” refers to an axis that makes a half of a closed curve and the other half match each other when one face is folded based on one axis crossing the closed curve corresponding to a contour of the one face. For example, in the case of the first face A and the second face B illustrated in FIGS. 8 and 9A, a symmetrical axis does not exist because each of the first face A and the second face B is not symmetrical by any axis crossing a closed curve that is the outline of each of the first face A or the second face B. However, since each of the first face A and the second face B has two symmetrical axes 51 in the case of the first face A and the second face B having rectangular shapes illustrated in FIG. 9B, two symmetrical axes 51 in the case of the first face A and the second face B having rhombus shapes illustrated in FIG. 9C, and one symmetrical axis 51 in the case of the first face A and the second face B having isosceles triangle shapes illustrated in FIG. 9D, the first face A and the second face B correspond to symmetrical surfaces having a symmetrical shape.

Consequently, in the LED structure 100 shown in FIG. 7, the first face A and the second face B are asymmetric faces without having a symmetrical axis, and thus, the first face A and the second face B are in a congruent relationship in which an inverted shape of the first face A is completely overlapped with the second face B. However, since the first face A and the second face B are overlapped with each other only when any one of the shape of the first face A and the shape of the second face B is inverted, it can be said that the shape of the first face A and the shape of the second face B are not identical to each other.

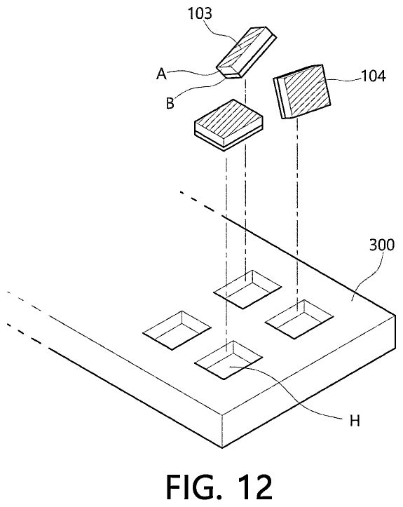

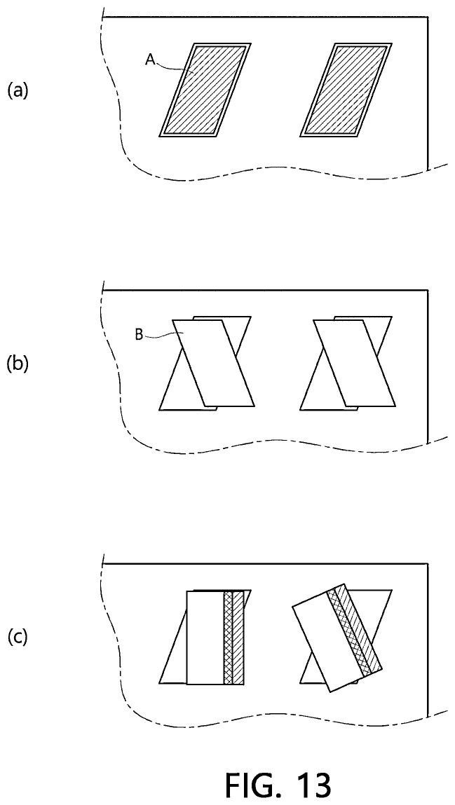

On the other hand, when the LED structure 100 is implemented such that the first face A and the second face B have shapes congruent with each other but have asymmetric shapes in which a symmetrical axis does not exist, the alignment surface and the alignment direction of each of the plurality of LED structures 100 can be controlled when the plurality of LED structures 100 are mounted on the electrodes with the help of the alignment guide part 300 that has the hole passing therethrough so as to have the same shape as the shape of the first face A or the shape of the second face B. When describing this with reference to FIGS. 12 and 13(a)-13(c), as illustrated in the drawings, when a plurality of LED structures 103 and 104 are processed in the alignment guide part 300 having a plurality of holes H each passing therethrough so as have the same shape as a shape of a first face A of each of the LED structures 103 and 104, only a second face B side end portion of each of the LED structures 103 and 104 can be inserted into the hole H as shown in FIG. 13(a), and a first face A side end portion of each of the LED structures 103 and 104, which has the same shape as an inverted shape thereof when viewed from the top of the alignment guide part 300, is not inserted into the hole H having the same shape as the first face A and passing through the alignment guide part 300.

Thus, when the plurality of LED structures are scattered on the lower electrodes through printing or the like and then self-aligned, the alignment surface of each of the LED structures aligned on the lower electrodes is controlled to be a specific surface, that is, the first face A or the second face B with the help of the alignment guide part 300 as described above, and in this case, all elements are aligned in the first direction on the first electrodes 201, 202, and 203, thereby increasing top emission. In addition, all LED structures can be aligned such that the first face A or the second face B is in contact with the first electrode 201, 202, or 203, and thus, a display can be driven by direct current (DC) can be implemented.

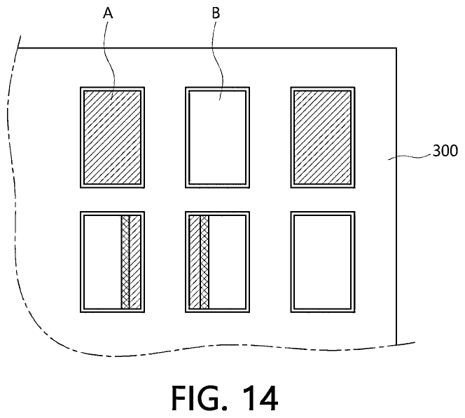

On the other hand, in the case of LED structures each having a first face A and a second face B of a rectangular shape having a symmetrical axis as shown in FIG. 9B, the first face A, the second face B, and remaining side faces may have a rectangular shape having a symmetrical axis. Accordingly, as shown in FIG. 14, since the LED structure may be inserted into the hole of the alignment guide part 300 such that any one face of the first face A, the second face B, and the side faces becomes the alignment face, even though the LED structures can be mounted on the first electrode, some LED structures may be short circuited and may not emit light because the side faces thereof may be located on the first electrode, and the remaining LED structures may be mounted on the first electrode such that any one of the first face A and the second face B becomes the alignment face, and thus, there may be a limitation in the selection of driving power, in which a display cannot driven by DC power.

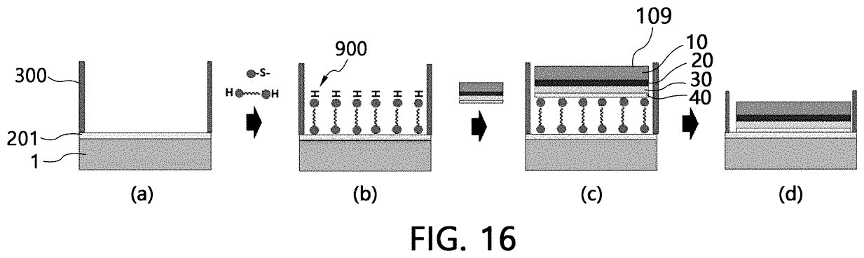

Further, according to one embodiment of the present disclosure, a shape of each of the remaining faces of the LED structure 100 except for the first face A and the second face B is different from the shape of at least one of the first face A and the second face B, and thus, when the LED structures 100 are randomly arranged on the lower electrode and then aligned, the case in which the LED structures 100 are aligned such that any one surface of the LED structure 100 other than the first face A and the second face B comes into contact with the first electrode can be prevented. As an example, as shown in FIG. 16(c), a shape of a side face of each of the LED structures 103 and 104 is a rectangular shape and is not the same as the shape of the first face A or the second face B, and accordingly, the side face of each of the LED structures 103 and 104 cannot be inserted into the holes H of the alignment guide part 300, so that the side surface of each of the LED structures 103 and 104 may be prevented from becoming the alignment face.

Meanwhile, the present disclosure does not particularly limit the shape of each of the remaining faces as long as the shape of each of the remaining faces of the LED structure 100 except for the first face A and the second face B is different from the shape of any one of the first face A and the second face B, and the shape of each of the remaining faces may be, for example, a rectangular shape, a square shape, or a parallelogram shape.

Further, in the LED structures 100 described above, each of the first face A and the second face B may have an area of 0.20 μm² to 100 μm², and a thickness of the LED structure 100, which is a vertical distance between the first face A and the second face B, may be in a range of 0.3 μm to 3.5 μm, which may be advantageous for achieving the purpose of the present disclosure. Particularly, when the LED structure is manufactured so that the thickness thereof is 3.5 μm or less, as an example, a moving distance of holes and electrons passing through a p-type semiconductor layer and an n-type semiconductor layer corresponding to the second conductive semiconductor layer 30 and the first conductive semiconductor layer 10 may be significantly reduced, in particular, holes having very low mobility than electrons may move a shorter distance, so that movement loss due to the movement distance can be minimized, thereby greatly improving light emission efficiency. However, when the thickness is less than 0.3 μm, a thickness of the n-type semiconductor layer may be relatively thinner than that of the p-type semiconductor layer, and thus a position at which electrons and holes are combined may deviate from the photoactive layer, thereby greatly reducing light emission efficiency.

Meanwhile, even when the thickness, which is the vertical distance between the first face A and the second face B, is within the preferred range described above, the location at which electrons and holes are combined may deviate from the photoactive layer due to a mobility difference between electrons and holes as described above. That is, when a large-area LED wafer is etched to implement the LED structures, thicknesses of the first conductive semiconductor layer, the photoactive layer, and the second conductive semiconductor layer are already determined in a state of the LED wafer, but only portions thereof are etched to a thickness different from a thickness of each of the layers in the wafer to implement the LED structure, and thus, such a problem inevitably occurs. Such a change in position at which electrons and holes are combined is caused due to a difference in velocity between electrons and holes moving in conductive semiconductor layers, which are an n-type semiconductor and a p-type semiconductor. For example, in an n-type GaN conductive semiconductor layer, electrons have a mobility of 200 cm²/Vs, and in a p-type GaN conductive semiconductor layer, holes have a mobility of only 5 cm²/Vs, and thus, due to such an electron-hole velocity imbalance, a position at which electrons and holes are combined may vary according to a thickness of the p-type GaN conductive semiconductor layer and a thickness of the n-type GaN conductive semiconductor layer and may deviate from the photoactive layer.

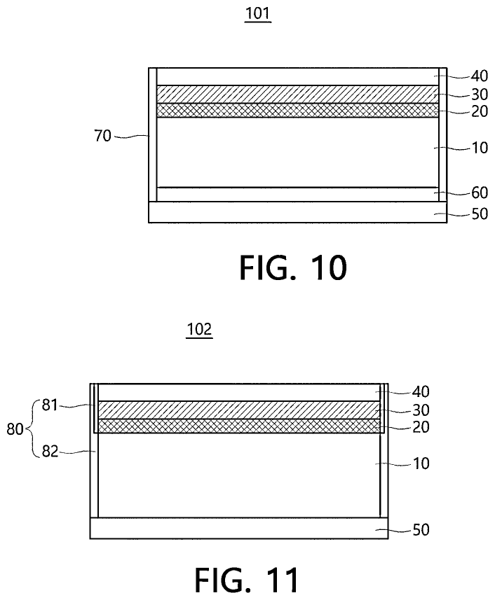

In order to solve such a problem, as shown in FIG. 10, an LED structure 101 used in one embodiment of the present disclosure may be implemented to further include an electron delay layer 60 adjacent to a lower portion of the first conductive semiconductor layer 10, when the first conductive semiconductor layer 10 is an n-type semiconductor layer so as to balance the numbers of holes and electrons recombined in the photoactive layer to prevent a degradation in light emission efficiency, and thus, even when a thickness of the first conductive semiconductor layer 10, which is an n-type semiconductor layer, is implemented to be thin, it is possible to prevent a degradation in light emission efficiency due to the change of the position at which electrons and holes are combined. In addition, the reduced thickness of the first conductive semiconductor layer 10 may decrease the probability that electrons are captured by surface defects while moving in a thickness direction of the first conductive semiconductor layer 10, thereby minimizing light emission loss and thus achieving greater light emission efficiency.

The electron delay layer 60 may include, for example, at least one selected from the group consisting of CdS, GaS, ZnS, CdSe, CaSe, ZnSe, CdTe, GaTe, SiC, ZnO, ZnMgO, SnO₂, TiO₂, In₂O₃, Ga₂O₃, S₁, poly(paraphenylene vinylene) and derivatives thereof, polyaniline, poly(3-alkylthiophene), and poly(paraphenylene). Alternatively, when the first conductive semiconductor layer 10 is a doped n-type Group III-nitride semiconductor layer, the electron delay layer may be a III-nitride semiconductor having a doping concentration lower than that of the first conductive semiconductor layer 10. In addition, the electron delay layer 60 may have a thickness of 1 nm to 100 nm, but the present disclosure is not limited thereto, and the thickness of the electron delay layer 60 may be appropriately changed in consideration of a material of an n-type conductive semiconductor layer, a material of the electron delay layer, and the like.

Hereinafter, each layer constituting the LED structure 100 or 101 according to one embodiment of the present disclosure will be described in detail.

The LED structure 100 or 101 is formed by stacking layers including the first conductive semiconductor layer 10, the photoactive layer 20, and the second conductive semiconductor layer 30 in the first direction.

In this case, one of the first conductive semiconductor layer 10 and the second conductive semiconductor layer 30 may be an n-type semiconductor layer, and the other thereof may be a p-type semiconductor layer. A known semiconductor layer applied to an LED may be used as the n-type semiconductor layer and the p-type semiconductor layer without limitation. As an example, the n-type semiconductor layer and the p-type semiconductor layer may include Group III-V semiconductors referred to as III-nitride materials, in particular, binary, ternary, and quaternary alloys of gallium, aluminum, indium, and nitrogen.

As an example, the first conductive semiconductor layer 10 may be an n-type semiconductor layer, and in this case, the n-type semiconductor layer may include a semiconductor material having a composition formula of InₓAl_{y}Ga_{1-x-y}N (0≤x≤1, 0≤y≤1, and 0≤x+y≤1), for example, at least one selected from among InAlGaN, GaN, AlGaN, InGaN, AlN, InN, and the like and may be doped with a first conductive dopant (for example, S₁, Ge, Sn, or the like). According to one exemplary embodiment of the present disclosure, the first conductive semiconductor layer 10 may have a thickness of 100 nm to 3,000 nm, but the present disclosure is not limited thereto.

Further, the second conductive semiconductor layer 30 may be a p-type semiconductor layer, and in this case, the p-type semiconductor layer may include a semiconductor material having a composition formula of InₓAl_{y}Ga_{1-x-y}N (0≤x≤1, 0≤y≤1, and 0≤x+y≤1), for example, at least one selected from among InAlGaN, GaN, AlGaN, InGaN, AlN, InN, and the like and may be doped with a second conductive dopant (for example, Mg). According to one exemplary embodiment of the present disclosure, the second conductive semiconductor layer 30 may have a thickness of 50 nm to 150 nm, but the present disclosure is not limited thereto.

Further, the photoactive layer 20 located between the first conductive semiconductor layer 10 and the second conductive semiconductor layer 30 may be formed to have a single or multi-quantum well structure. A photoactive layer included in a typical LED element used for lighting, a display, and the like may be used as the photoactive layer 20 without limitation. A clad layer (not shown) doped with a conductive dopant may be formed above and/or below the photoactive layer 20, and the clad layer doped with the conductive dopant may be implemented as, for example, an AlGaN layer or an InAlGaN layer. In addition, a material such as AlGaN or AlInGaN may also be used for the photoactive layer 20. In the photoactive layer 20, when an electric field is applied to an element, electrons and holes moving from the conductive semiconductor layers located above and below the photoactive layer to the photoactive layer are recombined to generate electron-hole pairs in the photoactive layer, thereby emitting light. According to one exemplary embodiment of the present disclosure, the photoactive layer 20 may have a thickness of 50 nm to 200 nm, but the present disclosure is not limited thereto.

Meanwhile, a second electrode layer 50 may be provided below the first conductive semiconductor layer 10 described above and/or a first electrode layer 40 may be further provided above the second conductive semiconductor layer 30.

An electrode layer included in a typical LED element used for a display may be used as the first electrode layer 40 and the second electrode layer 50 without limitation. The first electrode layer 40 and the second electrode layer 50 are each independently a single layer made of one selected from among Cr, Ti, Al, Au, Ni, ITO, and oxides or alloys thereof, a single layer made of two or more thereof, or a composite layer in which two or more materials thereof each constitute a layer. As an example, the LED structure may include a first electrode layer in which an ITO layer and a Ti/Au composite layer are stacked on the second conductive semiconductor layer 30. In addition, the first electrode layer 40 and the second electrode layer 50 may each independently have a thickness of 10 nm to 500 nm, but the present disclosure is not limited thereto.

Further, the LED structure 101 may further include a protective film 70 covering the remaining faces except for the first face A and the second face B. The protective film 70 serves to protect surfaces of the first conductive semiconductor layer 10, the photoactive layer 20, and the second conductive semiconductor layer 30. In addition, in a process of etching an LED wafer in a thickness direction thereof and then separating a plurality of LED pillars, the protective film 70 may serve to protect the semiconductor layer including the first conductive semiconductor layer 10 and the photoactive layer. The protective film 70 may include, for example, at least one from among silicon nitride (Si₃N₄), silicon dioxide (SiO₂), aluminum oxide (Al₂O₃), hafnium oxide (HfO₂), zirconium oxide (ZrO₂), yttrium oxide (Y₂O₃), titanium dioxide (TiO₂), aluminum nitride (AlN), and gallium nitride (GaN). In addition, the protective film 70 may have a thickness of 5 nm to 100 nm and more preferably a thickness of 30 nm to 100 nm, which may be advantageous in protecting the first conductive semiconductor layer 10 corresponding to an n-type semiconductor layer in a process of separating the LED pillar formed after etching the LED wafer from the wafer body,

Meanwhile, as shown in FIG. 11, an LED structure 102 according to one embodiment of the present disclosure may include a functional film 80 that includes a hole pushing film 81 configured to surround exposed side surfaces of a second conductive semiconductor layer 30 or the exposed side surfaces of the second conductive semiconductor layer 30 and exposed side surfaces of at least a portion of a photoactive layer 20 to move holes on the exposed side surface toward a center, and an electron pushing film 82 configured to surround exposed side surfaces of a first conductive semiconductor layer 10 to move electrons on the exposed side surface toward a center in order to have a protection function as a protective film and also to improve light emission efficiency.

Specifically, when an n-type semiconductor layer is referred to as the first conductive semiconductor layer 10, some of the charges moving from the first conductive semiconductor layer 10 to the photoactive layer 20 and some of the holes moving from the second conductive semiconductor layer 30 to the photoactive layer 20 may move along a surface of a side surface of the LED structure, and in this case, quenching of electrons or holes may occur due to defects present on the surface, and thus, light emission efficiency may be degraded. In this case, even when a protective film surrounding the side surface of the LED structure is provided, quenching is unavoidable due to defects occurring at the surface of the side surface of the LED structure before the protective film is formed. However, when the functional film 80 includes the hole pushing film 81 and the electron pushing film 82, electrons and holes may be concentrated toward an element center and guided to move in a direction of the photoactive layer 20, and thus, even when defects are present on the surface of the side surface of the LED structure before the functional film 80 is formed, there is an advantage in that loss of light emission efficiency due to surface defects may be prevented.

The hole pushing film 81 may include, for example, at least one selected from the group consisting of AlN_{X}, ZrO₂, MoO, Sc₂O₃, La₂O₃, MgO, Y₂O₃, Al₂O₃, Ga₂O₃, TiO₂, ZnS, Ta₂O₅, and n-MoS₂, and the electron pushing film 82 may include at least one selected from the group consisting of Al₂O₃, HfO₂, SiNₓ, SiO₂, ZrO₂, Sc₂O₃, AlNₓ, and Ga₂O₃.

Further, as shown in FIG. 11, when the LED structure 102 includes both the hole pushing film 81 and the electron pushing film 82, the electron pushing film 82 may be provided as an outermost film surrounding side surfaces of the first conductive semiconductor layer 10, the photoactive layer 20, and the second conductive semiconductor layer 30.

Further, the hole pushing film 81 and the electron pushing film 82 may each independently have a thickness of 1 nm to 50 nm.

Meanwhile, it should be noted that the first conductive semiconductor layer 10, the photoactive layer 20, and the second conductive semiconductor layer 30, which are described above, may be included as minimum components of the LED structure, and another phosphor layer, a quantum dot layer, an active layer, a semiconductor layer, a hole blocking layer, and/or an electrode layer may be further included above/below each layer.

Since the above-described LED structure 100 or 101 according to one embodiment of the present disclosure may be manufactured by appropriately employing a known method for manufacturing individual isolated LED elements through an LED wafer, in the present disclosure, the manufacturing method of the LED structure 100 or 101 is not particularly limited. However, when an area of the first face A of the LED structure 100 or 101 is considered, the LED structures etched from the LED wafer may not be easily separated into individual structures when the LED structure 100 or 101 is manufactured to have a small thickness.

Accordingly, the LED structure 100 or 101 provided in one embodiment of the present disclosure may be manufactured by including operation (A) of patterning an upper portion of an LED wafer, which is obtained by stacking at least an n-type semiconductor layer corresponding to a first conductive semiconductor layer, a photoactive layer, and a p-type semiconductor layer corresponding to a second conductive semiconductor layer, to have a desired shape of a first face A, and then vertically etching a first conductive semiconductor layer 10 to at least a partial thickness thereof to form a plurality of LED structures whose bottom surfaces are not separated from an LED wafer body, operation (B) of forming a protective film so as to surround an exposed surface of each of the plurality of LED structures but exposes an upper surface of the first conductive semiconductor layer located between the adjacent LED structures to the outside, operation (C) of immersing the LED wafer in an electrolyte, electrically connecting the LED wafer to one terminal of a power supply, electrically connecting the other electrode of the power supply to an electrode immersed in the electrolyte, and then applying power to form a plurality of pores in a portion of the first conductive semiconductor layer located below the plurality of LED structures that are not separated from the LED wafer body, and operation (D) of applying ultrasonic waves to the LED wafer to separate the plurality of LED structures from the portion of the first conductive semiconductor layer in which the plurality of pores are formed.

In this case, as patent documents by the inventor of the present disclosure, Korean Patent Application Nos. 10-2020-0189204 and 10-2020-0189203 are incorporated by reference in their entirety in the method of manufacturing the LED structure 100 or 101 including operations (A) to (D), and thus, detailed descriptions of the method of manufacturing the LED structure 100 or 101 including operations (A) to (D) will be omitted.

When the LED structure is manufactured according to the above-described patent documents by the inventors of the present disclosure, the surface of the bottom surface of the separated LED structure can be easily and smoothly separated from the LED wafer body even when the LED structure is manufactured by increasing an area of the first face A and etching the LED structure to a relatively small thickness, or the first face A has a non-standardized shape, which may be advantageous for minimizing physical/chemical damage of the separated LED structure and obtaining the LED structure with minimal reduction in light emission efficiency.

Further, a method of manufacturing an LED structure having a functional film 80 as shown in FIG. 11 can also be performed by the above-described manufacturing method disclosed in the patent documents incorporated by reference herein, and a detailed description thereof will be omitted in the present disclosure.

Further, according to one embodiment of the present disclosure, a conductive metal layer (not shown) configured to connect the first electrode 201, 202, or 203 and one side of the LED structure 100 in contact with the first electrode 201, 202, or 203 may be further included in order to reduce contact resistance between the first electrode 201, 202, or 203 and the LED structure 100. The conductive metal layer may be a conductive metal layer such as silver, aluminum, gold, or the like, and for example, may be formed to have a thickness of about 10 nm. Specifically, the conductive metal layer may be disposed in a spacing space between an inner wall of the hole H of the alignment guide part 300 and the LED structures 100.

Further, an insulating layer 400 may be further included in a space between the LED structures 100 disposed on the lower electrode line part 200 and the upper electrode line part 500 in electrical contact with the upper portions of the LED structure 100s. The insulating layer 400 prevents electrical contact between the two electrode line parts 200 and 500 facing each other in a vertical direction, and serves as a flat surface capable of more easily implementing the upper electrode line part 500.

Further, the color conversion part 700 in which a blue color conversion layer 701, a green color conversion layer 703, and a red color conversion layer 702 are patterned is included on the upper electrode line part 500 so that each of the plurality of sub-pixel sites S₁, S₂, S₃, and S₄ becomes a sub-pixel site that independently expresses any one color among blue, green, and red. The blue color conversion layer 701, the green color conversion layer 703, and the red color conversion layer 702 may each be a known color conversion layer that converts light passing through the color conversion layer to have blue, green, and red colors in consideration of a wavelength of the light emitted by the LED structure 100 provided in the sub-pixel sites S₁, S₂, S₃, and S₄, and thus, the present disclosure is not particularly limited thereto. Meanwhile, when the LED structure 100 is an element that emits blue light, the color conversion part 700 may include a green color conversion layer and a red color conversion layer because the blue color conversion layer 701 is not required. In addition, a blue scattering layer configured to perform a function of improving a light distribution profile for the top emission of blue light may be further provided in place of the blue color conversion layer 701. The blue scattering layer may employ a blue scattering layer known to perform the above function without limitation and may be, for example, a polymer coating layer in which light scattering components such as silica beads, titanium dioxide particles, zirconia particles, silica colloid particles, air bubbles, and phosphor colloids are dispersed.

Further, a short-wavelength transmission filter 800 may be further provided in each of the sub-pixel sites S₂ and S₃ corresponding to the green color conversion layer 703 and the red color conversion layer 702.

Further, a protective layer 600 for protecting the color conversion part 700 described above may be further provided, and a protective layer used in a conventional display in which the color conversion part 700 is provided may be appropriately employed as the protective layer 600, and thus the present disclosure is not particularly limited thereto.

The above-described full-color LED display 1000 according to the first embodiment may be manufactured by a manufacturing method to be described below. Specifically, the full-color LED display 1000 may be manufactured by including operation (1) of preparing a lower electrode line part including at least one first electrode and having a plurality of sub-pixel sites formed on a main surface of the first electrode, operation (2) of forming an alignment guide part, which covers at least a main surface portion of the first electrode corresponding to each of the sub-pixel sites and includes at least two holes each passing through a portion thereof corresponding to each of the sub-pixel sites so as to have a first shape, on the lower electrode line part, operation (3) printing an ink composition (for a printing apparatus) including a plurality of LED structures, each of which emits light of substantially the same color, includes a first conductive semiconductor layer, a photoactive layer, and a second conductive semiconductor layer, which are stacked in a first direction, and includes a first face and a second face facing each other in the first direction, wherein a shape of the second face and a shape of the first face, which is the first shape, are congruent with each other, but the shape of the first face and the shape of the second face have an asymmetric shape in which a symmetrical axis does not exist, on a region of the alignment guide part corresponding to each of the sub-pixel sites, operation (4) of aligning the plurality of LED structures on the main surface of the first electrode by inserting a second face side end portion of each of the LED structures placed on the alignment guide part into the hole of the alignment guide part, operation (5) of forming an upper electrode line part including at least one second electrode on the plurality of aligned LED structures so as to be in contact with the first face of the LED structure, and operation (6) of patterning a color conversion part on the second electrode corresponding to the sub-pixel site so that the sub-pixel sites become sub-pixel sites each expressing any one of blue, green, and red colors in each of the plurality of sub-pixel sites.

Hereinafter, the content of the full-color LED display 1000 described above will be omitted from the description of the manufacturing method.

When described with reference to FIGS. 1 to 3(a)-3(f), as operation (1) according to the present disclosure, preparing a lower electrode line part 200 including first electrodes 201, 202, and 203 and having a plurality of sub-pixel sites formed on main surfaces of the first electrodes 201, 202, and 203 is performed.

The first electrodes 201, 202, and 203 may be implemented in various known electrode patterns known in the art, and the present disclosure is not particularly limited thereto. As an example, as shown in FIG. 1, the plurality of first electrodes 201, 202, and 203 may be implemented in patterns arranged in parallel to each other with a predetermined interval therebetween. The first electrodes 201, 202, and 203 may be formed on a substrate 1, and as the substrate 1, for example, any one of a glass substrate, a quartz substrate, a sapphire substrate, a plastic substrate, and a flexible polymer film that is bendable may be used may be used. As another example, the substrate 1 may be transparent. However, the present disclosure is not limited to the listed types, and any type of substrate capable of generally forming an electrode may be used. An area of the substrate 1 is not limited, and may vary in consideration of an area of the first electrodes 201, 202, and 203 formed on the substrate 1 or a size of a display to be implemented. In addition, the substrate 1 may have a thickness of 100 μm to 1 mm, but the present disclosure is not limited thereto.

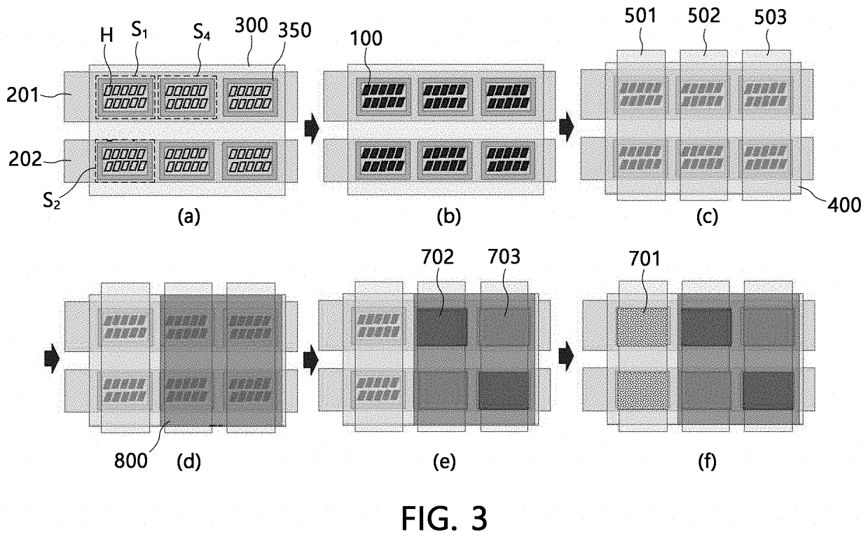

Next, as operation (2) according to the present disclosure, forming an alignment guide part 300, which covers at least a main surface portion of each of the first electrodes 201, 202, and 203 corresponding to each of the sub-pixel sites S₁, S₂, S₃, and S₄ and includes at least two holes H each passing through a portion thereof corresponding to each of the sub-pixel sites S₁, S₂, S₃, and S₄ so as to have a first shape, on the lower electrode line part 200 (refer to FIG. 3(a)) is performed.

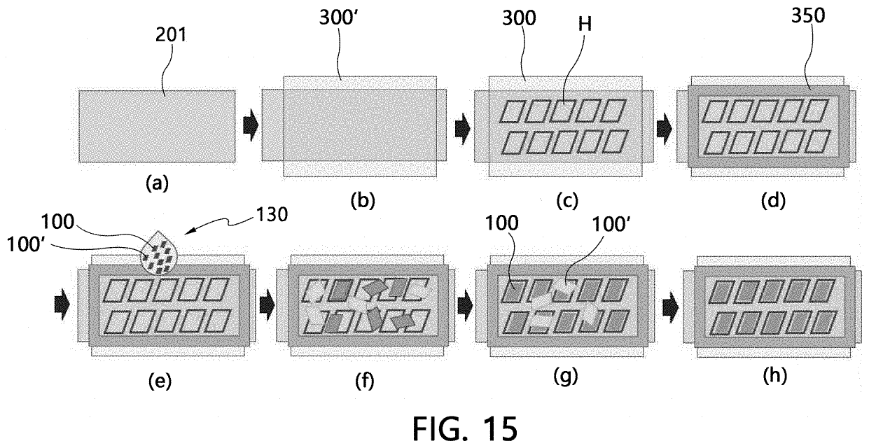

Operation (2) is an operation of preparing a region in which the LED structures 100 are to be printed, and in operation (2), the alignment guide part 300 having a plurality of holes, each of which passes therethrough so as to have the same shape as the first face A of the LED structure 100, is formed on the first electrodes 201, 202, and 203. When describing this with reference to FIG. 15(a)-15(h), a body 300′ of an alignment guide part is formed (see FIG. 15(b)) to a predetermined thickness on the main surface of the first electrode 201 prepared as shown in FIG. 15(a), and then a plurality of holes H each passing through the alignment guide part so as to have the same shape as the shape of the first face A of the LED structure 100 are formed, thereby forming the alignment guide part 300 (see FIG. 15(c)) In this case, the body 300′ of the alignment guide part, which is an origin of the alignment guide part 300, may be formed through a conventional deposition method in consideration of a material thereof. As an example, when the material is an inorganic material, the body 300′ of the alignment guide part may be formed by any one among a chemical vapor deposition method, an atomic layer deposition method, a vacuum deposition method, an e-beam deposition method, and a spin coating method. In addition, when the material is a polymer insulating material, the body 300′ of the alignment guide part may be formed by a coating method such as spin coating, spray coating, and screen printing.

Further, the holes H may be formed by forming a plurality of pattern layers on an upper surface of the body 300′ of the alignment guide part so as to have the same shape as the shape of the first face A of the LED structure, and then etching the pattern layers by a thickness of the body 300′ of the alignment guide part. Here, the pattern layer may be a pattern formed through photolithography using a photosensitive material, or formed through a known nano imprinting method, laser interference lithography, electron beam lithography, or the like. In addition, the etching may employ a suitable known etching method according to the material of the body 300′ of the alignment guide part, and for example, may be performed through a dry etching method using reactive ion etching (RIE).

Further, the hole H may be formed in a region corresponding to the main surface of the first electrode 201 such that at least a portion of the main surface of the first electrode 201 is located inside the hole H. In other words, the specific formation position and size of the hole H may be changed in consideration of the shape and size of the LED structure, the width of the first electrode, and the number of first electrodes in contact with one surface of the LED structure. As an example, in the case of the hole H illustrated in FIG. 15(a)-15(h), the hole H may be formed such that the main surface of one first electrode 201 is located inside the hole H. Alternatively, as illustrated in FIG. 17, the hole H may be formed such that a portion of a main surface of the first electrode 211 and a portion of a main surface of the adjacent first electrode 212 are present inside one hole H.

Further, according to one embodiment of the present disclosure, operation (2) may further include a process of forming a partition wall 350 surrounding a region, in which the plurality of holes H are formed, on the alignment guide part 300 (see FIG. 15(d)). The partition wall 350 may be made of an insulating material so as not to provide an electrical influence when the LED structure is driven in a final LED electrode assembly implemented by mounting the LED structure therein. In this case, when the material is an inorganic insulating material, the partition wall 350 may be formed on the alignment guide part 300 by any one among a chemical vapor deposition method, an atomic layer deposition method, a vacuum deposition method, an e-beam deposition method, and a spin coating method. In addition, when the material is a polymer insulating material, the partition wall 350 may be formed on the alignment guide part 300 by a coating method such as spin coating, spray coating, or screen printing. In addition, the patterning may be performed by photolithography using a photosensitive material, or performed by a known nano imprinting method, laser interference lithography, electron beam lithography, or the like. At this point, a thickness of the insulating material, which will become the partition wall 350, is ½ or more of a thickness of the LED structure, and may be preferably in a range of 0.1 μm to 100 μm, and more preferably 0.3 to 10 μm as a thickness that may not normally affect post-processing. When the above-described range is not satisfied, which may affect a post process, and thus it may be difficult to manufacture a display. In particular, when a thickness of the insulating material is too small as compared to the thickness of the LED structure, the effect of preventing the spread of the LED structure through the partition wall may be insufficiently achieved, and there is a risk that the ink composition including the LED structures may overflow out of the partition wall.

Further, the etching may adopt a suitable etching method in consideration of the material of the insulating material, and may be performed by, for example, a wet etching method or a dry etching method. Preferably, the etching may be performed by one or more dry etching methods among plasma etching, sputter etching, reactive ion etching, and reactive ion beam etching.

Next, as operation (3) according to the present disclosure, printing an ink composition 130 (for a printing apparatus) including a plurality of LED structures 100 and 100′, each of which emits light of substantially the same color, includes a first conductive semiconductor layer 10, a photoactive layer 20, and a second conductive semiconductor layer 30, which are stacked in a first direction, and includes a first face A and a second face B facing each other in the first direction, wherein a shape of the second face B and a shape of the first face A, which is the first shape, are congruent with each other, but the shape of the first face A and the shape of the second face B have an asymmetric shape in which a symmetrical axis does not exist, on a region of the alignment guide part 300 corresponding to each of the sub-pixel sites S₁, S₂, S₃, and S₄ is performed.

The plurality of LED structures 100 and 100′ are prepared as an ink composition 130 in which the plurality of LED structures 100 and 100′ are formed into ink. The ink composition 130 may further include a dispersion medium, other additives, and the like provided in a typical ink composition used for the corresponding printing apparatus in consideration of a specific type of the printing apparatus to be used, and the present disclosure is not particularly limited thereto. In addition, physical properties such as viscosity of the ink composition 130 may adopt physical properties such as viscosity of a typical ink composition used for a printing apparatus and may be appropriately changed, and thus the present disclosure is not particularly limited thereto.

Further, the ink composition 130 for a printing apparatus is printed on a region in which the LED structures 100 and 100′ are to be mounted, that is, a region of the alignment guide part 300 corresponding to each of the sub-pixel sites S₁, S₂, S₃, and S₄. In this case, when the partition wall 350 surrounding each of the sub-pixel sites S₁, S₂, S₃, and S₄ is further provided, the printed ink composition 130 is prevented from flowing out of a desired region, thereby increasing the probability of mounting the LED structures in the desired region.

Further, the ink composition 130 for a printing apparatus may be printed using a conventional printing apparatus, for example, may be printed through an inkjet printer, a 3D printer, a dispenser, or the like, and a specific printing method using a printing apparatus may be a known method for each apparatus, and thus the present disclosure is not particularly limited thereto.

Next, as operation (4) according to the present disclosure, aligning the plurality of LED structures on the main surface of the first electrode by inserting a second face B side end portion of each of the LED structures 100 and 100′ placed on the alignment guide part 300 into the hole of the alignment guide part 300 so as to 1:1 match each other is perform (see FIGS. 15(f) and 15(g)).

In operation (4), a method capable of easily changing and adjusting the position and direction of the LED structures 100 and 100′ such that the second face B side end portion of each of the LED structures 100 and 100′ is inserted into the hole H formed in the alignment guide part 300 by moving the LED structures 100 and 100′ can be used without limitation for arranging the LED structures 100 and 100′. As an example, operation (4) may be performed by radiating a sound wave one time or multiple times, and specifically, the LED structure can be moved, inserted, and aligned in the holes H in such a manner that a sound wave is radiated by appropriately adjusting the frequency, waveform, and amplitude of the sound wave, or two or more types of sound waves, in which at least one of a frequency, a waveform, and an amplitude is different, are radiated together or sequentially in consideration of an interval of the holes H formed in the alignment guide part 300, the size and movement distance of the LED structure, and the like. The sound wave may be radiated through a conventional sound wave generator, and the present disclosure is not particularly limited thereto.

Further, in operation (4), the LED structures 100 and 100′ may be moved, inserted, and aligned in the holes H by applying vibration together with the sound wave described above or by applying vibration independently without the sound wave, and the intensity or period of the applied vibration may be appropriately adjusted in consideration of the interval between the holes H formed in the alignment guide part 300 or a movement distance of the LED structures 100 and 100′, and thus the present disclosure is not particularly limited thereto.

Further, the LED structure 100′, which is not inserted and mounted in the hole H of the alignment guide part 300 or 301 after the sound wave or the like is applied, may finally be inserted and aligned in the hole H so that the second face B of the LED structure 100′ becomes the alignment surface, by inducing additional direction change of the LED structure by additionally applying the vibration or sound wave, changing the intensity or the like of the applied electric field, or additionally applying the vibration or sound wave together with the electric field.

Meanwhile, in the process of performing operation (4), there is a concern that the LED structure, whose second surface B side end portion is inserted and aligned in the hole H of the alignment guide part 300 or 301 prior to the other LED structures, may be separated from the hole H in a process of aligning the other LED structures that are not aligned, or in a process of performing a subsequent process after the LED structure is aligned. According to one embodiment of the present disclosure, in order to prevent the separation of the inserted and aligned LED structure, as shown in FIG. 16(a)-16(d), forming a chemical bonding linker 900 on the first electrode 201 formed on the substrate 1 may be further performed before operation (4) (see FIGS. 16(a) and 16(b)), and an LED structure 109 may include a first electrode layer 40 on at least one end thereof in the first direction, for example, on a second conductive semiconductor layer 30. Specifically, the chemical bonding linker 900 is for providing a bonding force between the first electrode layer 40 and the first electrode 201 of the LED structure 109 by inducing a chemical bond, and may be formed such that, for example, a thiol group, an amine group, a carboxyl group, single strand DNA or the like may be exposed to the outside. Specifically, the chemical bonding linker 900 may be formed through a compound such as aminoethanethol, 1,2-ethanedithiol, 1,4-butanedithiol, 3-mercaptopropionic acid, NH₂-terminated single-stranded DNA, or the like. In addition, the chemical bond may be a covalent bond or a non-covalent bond, and for example, when a thiol group is used as the chemical bonding linker, a non-covalent bond between the first electrode 201 and/or the first electrode layer 40, which is a metal, may be induced to provide a bonding force (see FIGS. 16(c) and 16(d)).

Further, in some cases, the chemical bonding linker may also be formed on the second face B of the LED structure differently from that shown in FIG. 16(a)-16(d), and a bonding force may be applied between the LED structures 100, 100′, and 108 and the first electrodes 201, 202, 203, 211, 212, 213, 214, 215, and 216 through a complementary bond between a first chemical bonding linker formed on the first electrodes 201, 202, 203, 211, 212, 213, 214, 215, and 216 and a second chemical bonding linker formed on the second face B of each of the LED structures 100, 100′, and 108. As an example, the first chemical bonding linker and the second chemical bonding linker may be an amine group and a carboxyl group, respectively, and an amide bond may be formed by bonding the amine group with the carboxyl group However, since a reaction rate is low when the amide bond is formed by bonding the amine group with the carboxyl group, 1-ethyl-3-(3′-dimethylaminopropyl)carbodiimide (EDC) may be added to form an active ester intermediate of the carboxyl group, followed by addition of a strong nucleophilic primary amine, thereby rapidly forming the amide bond. In addition, in order to stabilize the ester intermediate using EDC, sulfo N-Hydroxysuccinimide (NHS) may be used so that the amide bond may be stably performed.

Further, after operation (4) is performed and before operation (5) to be described below is performed, washing the LED structure 101′ which is not inserted and aligned may be performed, and through this, an intermediate structure, in which the LED structure 100 is inserted and aligned in the hole H formed in the alignment guide part 300, may be implemented (see FIG. 3(b) and FIG. 15(h)). As the washing operation, a conventional washing process may be applied, and for example, the washing operation may be performed through a method of spraying distilled water, acetone, isopropyl alcohol, or a mixed washing solution, or dipping the LED structure 101′ therein.

Thereafter, in the intermediate structure, heat-treating to improve electrical contact between the second face B of the LED structure 100 and the first electrodes 201, 202, and 203 and depositing the insulating layer 400 to fill a space between each LED structure 100 and the hole H into which the LED structure 100 is inserted and to planarize a space between the plurality of aligned LED structures 100 may be further performed (see FIGS. 15(l) and 15(m)) before operation (5) to be described below.

First, the heat treating performed to improve electrical contact between the second face B of the LED structure 100 and the first electrodes 201, 202, and 203 is an operation to achieve an ohmic contact therebetween, and for example, the heat treating may be performed by performing a rapid thermal annealing (RTA) process on interfaces between the first electrodes 201, 202, and 203 and the second face B of the LED structure 100. The RTA may be performed through a known RTA process performed to achieve an ohmic contact, and the present disclosure is not particularly limited thereto.

Further, depositing the insulating material to fill the space between each LED structure 100 and the hole H into which the LED structure 100 is inserted to fix the LED structure 100, and to planarize the space between the plurality of aligned LED structures 100 may be performed (see FIGS. 15(l) and 15(m)). The depositing of the insulating material is an operation of forming the insulating layer 400 to a predetermined thickness by as much as a height of the LED structure exposed above the alignment guide part 300 for electrical insulation from an upper electrode line part 500 to be formed in operation (5) to be described below. The insulating layer 400 may be formed through deposition of a known insulating material, for example, by depositing an insulating material such as SiO₂ or SiNₓ through a plasma-enhanced chemical vapor deposition (PECVD) method, or depositing an insulating material such as MN or GaN through a metal-organic chemical vapor deposition (MOCVD) method, or depositing an insulating material such as Al₂O, HfO₂, or ZrO₂ through an atomic layer deposition (ALD) method. Meanwhile, it is preferable that the insulating layer 400 is formed so as not to cover a surface of the first face A of the LED structure 100, which is inserted and aligned, and to this end, the insulating layer 400 may be formed through deposition to a thickness that does not cover the surface of the first face A of the LED structure 100 or 108, or, after depositing an insulating layer 400′ to a thickness covering the surface of the first face A of the LED structure 100 (see FIG. 15(l)), dry etching may be performed until the surface of the first face A of the LED structure 100 is exposed (see FIG. 15(m)).

Thereafter, as operation (5) according to the present disclosure, forming an upper electrode line part 500 including one or more second electrodes 501 and 502 on the plurality of aligned LED structures 100 so as to be in contact with the first face A of the LED structure 100 is performed (see FIG. 3(c)).

The upper electrode line part 500 may be implemented by depositing an electrode material after patterning the second electrodes 501 and 502 using known photolithography, or by depositing an electrode material and then performing dry and/or wet etching. Here, the electrode material may be a typical electrode material used as an electrode of an electrical/electronic material, and the present disclosure is not particularly limited thereto.

Thereafter, as operation (6) according to the present disclosure, a process of patterning the color conversion part 700 on the second electrodes 501 and 502 corresponding to the sub-pixel sites S₁, S₂, S₃, and S₄ may be performed so that the plurality of sub-pixel sites S₁, S₂, S₃, and S₄ respectively become the sub-pixel sites S₁, S₂, S₃, and S₄ each expressing any one of blue, green, and red colors (see FIG. 3(e)).

The LED structures 100 provided in the sub-pixel sites may emit blue light, white light, or UV light, and, in this case, a process of forming the color conversion part 700, which is capable of converting emitted light into light having a light color different from a light color of the emitted light for implementing a color image, on the sub-pixel sites may be performed. Preferably, color reproducibility may be improved by further enhancing color purity, a short-wavelength transmission filter 800 may be formed above the sub-pixel site to improve light emission efficiency of color converted light, for example, green/red light, of a front surface thereof so that light emission is changed from a rear surface of the color conversion layer to the front surface (see FIG. 3(d)), and a red color conversion layer 702 and a green color conversion layer 703 may be formed on an upper portion of the short-wavelength transmission filter 800.

When description is made based on a case in which the LED structure 100 is a blue LED element, the short-wavelength transmission filter 800 may be formed in a region including at least the upper electrode line part 500. The short-wavelength transmission filter 800 may be a multilayer film in which thin films made of highly refractive/poorly refractive materials are repeatedly formed, and a composition of the multilayer film may be [(0.125)SiO₂/(0.25)TiO₂/(0.125)SiO₂]ₘ (where m=the number of repeated layers, and m is 5 or more) to transmit a blue color and reflect a light color having a wavelength longer than the blue color. In addition, the short-wavelength transmission filter may have a thickness of 0.5 μm to 10 μm, but the present disclosure is not limited thereto. A method of forming the short-wavelength transmission filter may include one method among an e-beam method, a sputtering method, and an atomic layer deposition method, but the present disclosure is not limited thereto.

Next, the color conversion part 700 may be formed on the short-wavelength transmission filter 800, and specifically, the color conversion part 700 may be formed by patterning the green color conversion layer 703 on the short-wavelength transmission filter 800 corresponding to some sub-pixel sites selected from among the sub-pixel sites S₁, S₂, S₃, and S₄ and patterning the red color conversion layer 702 on the short-wavelength transmission filter 800 corresponding to some sub-pixel sites selected from among the remaining sub-pixel sites. The method of forming the patterns may be performed by one or more methods selected from the group consisting of a screen printing method, a photolithography method, and a dispensing method. Meanwhile, a patterning order of the green color conversion layer and the red color conversion layer is not limited, and the layers may be simultaneously formed or may be formed in reverse order. In addition, the red color conversion layer and the green color conversion layer may be color conversion layers known in lighting and display fields and may include, for example, a color conversion material such as a phosphor or the like that is excited by light emitted from a color filter, or a blue LED element and converts the light into light having a desired light color.

The color conversion material may include a known color conversion material. As an example, the green color conversion layer may be a phosphor layer including a green phosphor, and specifically, may include at least one phosphor selected from the group consisting of SrGa₂S₄:Eu, (Sr,Ca)₃SiO₅:Eu, (Sr,Ba,Ca)SiO₄:Eu, Li₂SrSiO₄:Eu, Sr₃SiO₄:Ce,Li, β-SiALON:Eu, CaSc₂O₄:Ce, Ca₃Sc₂Si₃O₁₂:Ce, Caα-SiALON:Yb, Caα-SiALON:Eu, Liα-SiALON:Eu, Ta₃Al₅O₁₂:Ce, Sr₂Si₅N₈:Ce, (Ca,Sr,Ba)Si₂O₂N₂:Eu, Ba₃Si₆O₁₂N₂:Eu, γ-AlON:Mn, and γ-AlON:Mn,Mg, but the present disclosure is not limited thereto. In addition, the green color conversion layer may be a phosphor layer including a green quantum dot material, and specifically, may include one or more quantum dots selected from the group consisting of CdSe/ZnS, InP/ZnS, InP/GaP/ZnS, InP/ZnSe/ZnS, and perovskite green nanocrystals, but the present disclosure is not limited thereto.

Further, the red color conversion layer may be a phosphor layer including a red phosphor, and specifically, may include one or more phosphors selected from the group consisting of (Sr,Ca)AlSiN₃:Eu, CaAlSiN₃:Eu, (Sr,Ca)S:Eu, CaSiN₂:Ce, SrSiN₂:Eu, Ba₂Si₅N₈:Eu, CaS:Eu, CaS:Eu,Ce, SrS:Eu, SrS:Eu,Ce, and Sr₂Si₅N₈:Eu, but the present disclosure is not limited thereto. In addition, the red color conversion layer may be a phosphor layer including a red quantum dot material, and specifically, may include one or more quantum dots selected from the group consisting of CdSe/ZnS, InP/ZnS, InP/GaP/ZnS, InP/ZnSe/ZnS, and perovskite red nanocrystals, but the present disclosure is not limited thereto.

In some sub-pixel sites, only the short-wavelength transmission filter is disposed on the uppermost layer and the green color conversion layer and the red color conversion layer are not formed on a vertical upper portion, and thus blue light may be radiated in such sites. On the other hand, green light may be radiated on some sub-pixel sites, at which the green color conversion layer is formed on the short-wavelength transmission filter, through the green color conversion layer. In addition, since the red color conversion layer is formed on the short-wavelength transmission filter at the remaining sub-pixel sites, red light may be radiated on the remaining sub-pixel sites, and thus a color-by-blue LED display may be implemented as the first embodiment.

Further, preferably, a long-wavelength transmission filter may be further formed on the upper portion including the green and red color conversion layers, and the long-wavelength transmission filter serves as a filter for preventing the color purity from being degraded by mixing the blue light emitted from the element and the color-converted green/red light. The long-wavelength transmission filter may be formed on some or all of the green color conversion layer and the red color conversion layer, and preferably, may be formed only on the green/red color conversion layers. Here, the usable long-wavelength transmission filter may be a multilayer film in which thin films made of highly refractive/poorly refractive materials, which are capable of achieving the purpose of transmission of light having a long wavelength and reflection of light having a short wavelength to reflect blue light, are repeatedly formed, and a composition of the multilayer film may be [(0.125)TiO₂/(0.25)SiO₂/(0.125)TiO₂]ₘ (where m=the number of repeated layers, and m is 5 or more). In addition, a long-wavelength transmission filter 1950 may have a thickness of 0.5 μm to 10 μm, but the present disclosure is not limited thereto. The method of forming the long-wavelength transmission filter may include one method among an e-beam method, a sputtering method, and an ALD method, but the present disclosure is not limited thereto. In addition, in order to form the long-wavelength transmission filter only on the green/red color conversion layers, the long-wavelength transmission filter may be formed only in a desired region using a metal mask capable of exposing the green and red color conversion layers and masking the other regions.

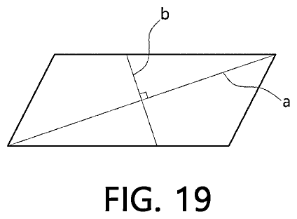

According to one embodiment of the present disclosure, as a modified example of the above-described full-color LED display 1000 according to the first embodiment, a full-color LED display 3000 illustrated in FIGS. 17 to 19 is illustrated. The full-color LED display 3000 according to the modified example is a case in which a mounting aspect of the first electrode and the LED structure is different from that of the full-color LED display 1000 illustrated in FIG. 1. The full-color LED display 1000 illustrated in FIG. 1 has a form in which the LED structure 100 is mounted on the main surface of one first electrode 201, 202, or 203, whereas the full-color LED display 3000 illustrated in FIG. 17 has a form in which the LED structure 100 is mounted over two adjacent first electrodes 211/212, 213/214, or 215/216, which is a different point from the full-color LED display 1000 illustrated in FIG. 1. Accordingly, a position in which a hole is formed in an alignment guide part 301 is also different from that in the full-color LED display 1000 illustrated in FIG. 1. However, other than those, forming an insulating layer 400 for planarizing a plurality of LED structures 108, disposing an upper electrode line part including a second electrode 510 on the plurality of aligned LED structures 108, and providing a color conversion part 700 or a protective layer 600 thereabove are the same as those in the full-color LED display 1000 illustrated in FIG. 1.

The full-color LED display 3000 illustrated in FIG. 17 may be applied to the LED structure 108 that has a shape elongated in a second direction perpendicular to the first direction. In addition, in the case of the LED structure 108 having the above-described shape, a conventional electric field induction method using an electric field as well as a sound wave may be adopted as a method of aligning the LED structures in operation (4) described above during a manufacturing process of the full-color LED display 3000. That is, when the LED structure has a shape elongated in one direction perpendicular to the first direction, the LED structure 108 can be easily inserted into a hole H of the alignment guide part 301 through electric field application.

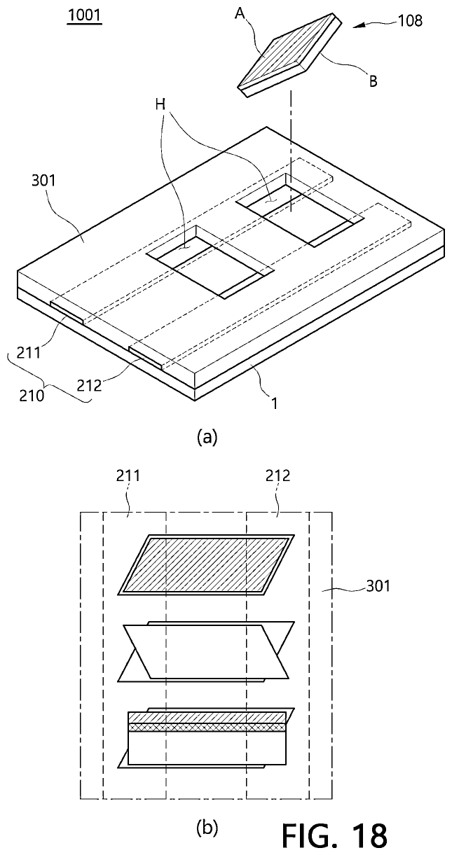

Specifically, when the LED structure 108 having an asymmetric face is a rod-type structure elongated in the second direction perpendicular to the first direction with an aspect ratio of a major axis a and a minor axis b of 2:1 or more in each of a first face A and a second face B, when an electric field is applied, both ends of the LED structure 108 are polarized to have different charges in the second direction, and thus, the LED structure may be mounted over two adjacent first electrodes 211/212, 213/214, or 215/216, to which different power is applied, in the second direction. In this case, as illustrated in FIG. 18(b), the first face A, the second face B, and a side surface of the LED structure 108 may be aligned on two first electrodes 211 and 212 adjacent to each other in the second direction, and when a second face B side one end of the LED structure 108, which matches the shape of the hole H of the alignment guide part 301, is located over the electrodes in the second direction, the LED structure may be mounted so as to be inserted into the hole H. On the other hand, in the other two cases, that is, when the first face A or the side surface is disposed adjacent to the two adjacent first electrodes 211 and 212, the first face A or the side surface may not be inserted and mounted in the hole H, and thus, an alignment surface and an alignment direction of the LED structure 108 may be controlled. In this case, an intensity of power applied to form an electric field may be set within a known voltage range used in a self-alignment process using an electric field, and the intensity of the power may be appropriately changed in consideration of the aspect ratio or size of the LED structure, and thus the present disclosure is not particularly limited thereto.

Meanwhile, it should be noted that the above-described full-color LED display 3000 corresponding to the modified example of the full-color LED display 1000 according to the first embodiment may also be implemented as a modified example of a second embodiment to be described below.

Next, a full-color LED display according to the second embodiment of the present disclosure will be described.

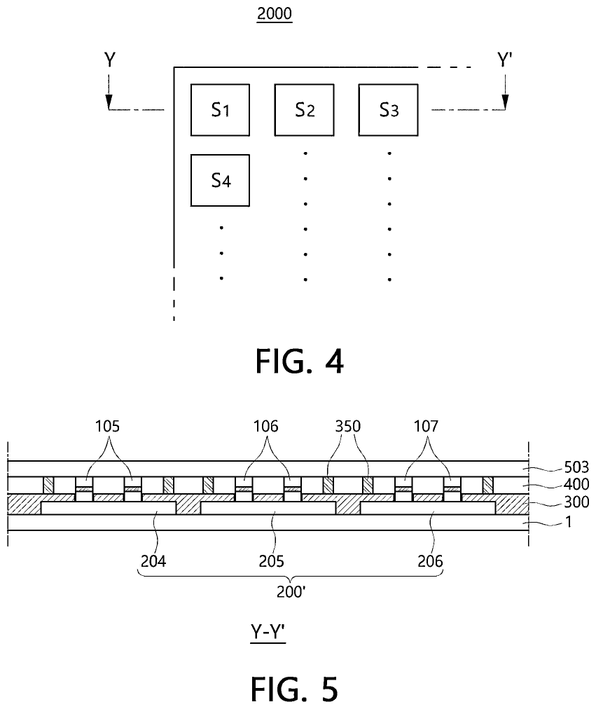

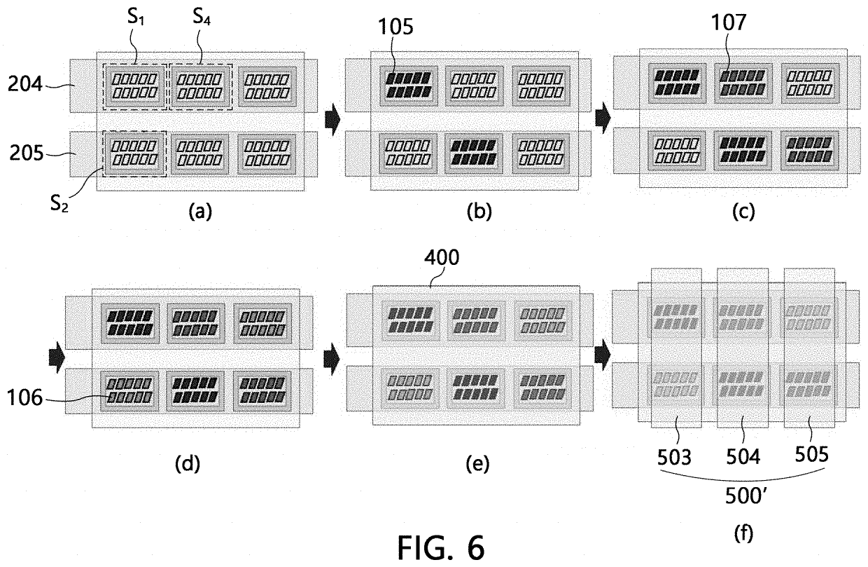

When described with reference to FIGS. 4 to 6(a)-6(f), a full-color LED display 2000 according to the second embodiment is implemented by including a lower electrode line part 200′ including one or more first electrodes 204, 205, and 206 and having a plurality of sub-pixel sites S₁, S₂, S₃, and S₄ formed on main surfaces of the first electrodes 204, 205, and 206, an alignment guide part 300 that covers at least a main surface portion of each of the first electrodes 204, 205, and 206 corresponding to each of the sub-pixel sites S₁, S₂, S₃, and S₄ and includes at least two holes H each passing through a portion corresponding to each of the sub-pixel sites S₁, S₂, S₃, and S₄ so as to have a first shape, a plurality of LED structures 105, 106, and 107, each of which includes a first conductive semiconductor layer, a photoactive layer and a second conductive semiconductor layer, which are stacked in the first direction, includes a first face and a second face facing each other in the first direction, and includes a blue LED structure 105, a green LED structure 106, and a red LED structure 107, each of which has a shape in which a shape of the second face and a shape of the first face, which is the first shape, are congruent with each other but the shape of the first face and the shape of the second face have an asymmetric shape in which a symmetrical axis does not exist, wherein each of the LED structures 105, 106, and 107 is disposed in each of the sub-pixel sites S₁, S₂, S₃, and S₄ so as to have substantially the same color of light, a second face side end portion of each of the LED structures 105, 106, and 107 is inserted into the hole H of the alignment guide part 300 such that the second face of each of the LED structures 105, 106, and 107 is brought into contact with the main surface of each of the first electrodes 204, 205, and 206, and aligned on the first electrodes 204, 205, and 206, and an upper electrode line part 500′ including one or more second electrodes 503, 504, and 506 disposed on the plurality of aligned LED structures 105, 106, and 107.

The above-described full-color LED display 1000 according to the first embodiment includes the LED structure 100 that emits light of substantially the same color, whereas the full-color LED display 2000 according to the second embodiment includes LED structures 105, 106, and 107 each using three types of elements each emitting blue light, green light, or red light, which is a different point from the full-color LED display 1000 according to the first embodiment, and in the full-color LED display 2000, at least two LED structures capable of emitting any one of blue light, green light, and red light are independently disposed for each of the sub-pixel sites S₁, S₂, S₃, and S₄. In addition, since the LED structure itself disposed in each of the sub-pixel sites S₁, S₂, S₃, and S₄ emits desired blue light, green light, or red light, a separate color conversion part is not required on the second electrode 503. Meanwhile, like the full-color LED display 1000 according to the first embodiment, the full-color LED display 2000 according to the second embodiment also commonly and essentially includes the first electrodes 204, 205, and 206, the alignment guide part 300, and the second electrode 503, and may further commonly include a substrate 1, a partition wall 350, and an insulating layer 400 disposed between the first electrodes 204, 205, and 206 and the second electrode 503, and descriptions thereof are the same as those of the full-color LED display 1000 according to the first embodiment, and thus detailed descriptions thereof will be omitted.

Further, the full-color LED display 2000 according to the second embodiment may be manufactured by including operation (I) of preparing a lower electrode line part including at least one first electrode and having a plurality of sub-pixel sites formed on a main surface of the first electrode, operation (II) of forming an alignment guide part, which covers at least a main surface portion of the first electrode corresponding to each of the sub-pixel sites and includes at least two holes each passing through a portion thereof corresponding to each of the sub-pixel sites so as to have a first shape, on the lower electrode line part, operation (III) of printing a blue LED structure ink composition, a green LED structure ink composition, and a red LED structure ink composition each including a plurality of LED structures for each light color, each of which includes a first conductive semiconductor layer, a photoactive layer, and a second conductive semiconductor layer which are stacked in the first direction, includes a first face and a second face facing each other in the first direction, wherein a shape of the second face and a shape of the first face, which is the first shape, are congruent with each other, but the shape of the first face and the shape of the second face have an asymmetric shape in which a symmetrical axis does not exist, and the ink compositions are printed on a region of the alignment guide part corresponding to each of the sub-pixel sites so that each of the plurality of sub-pixel sites independently expresses any one of blue, green, and red light colors, operation (IV) of aligning the plurality of LED structures by inserting a second face side end portion of each of the LED structures placed on the alignment guide part into the hole of the alignment guide part, and operation (V) of forming an upper electrode line part including at least one second electrode on the plurality of aligned LED structures so as to be in contact with the first face of the LED structure.

Each operation of the manufacturing method according to the second embodiment is the same as the manufacturing method according to the first embodiment except that in operation (II), three kinds of ink compositions including LED structures 205, 206, and 207 expressing three different colors are used, and thus a detailed description thereof will be omitted. In addition, it should be noted that an LED structure that emits light of a different color from the three light colors included in the second embodiment may be further used, and thus, the ink composition for the different color may also be included.

In a full-color light-emitting diode (LED) display according to the present disclosure, front luminance and light emission efficiency can be improved by solving the conventional problems of side light emission even for a display implemented by self-aligning nano- or micro-scale LED elements, electrodes for addresses can be easily arranged when implementing sub-pixels of a display, a display that can be driven even with a direct current (DC) power source can be implemented by easily controlling a mounting direction of the LED elements, and a large-area LED display can be easily implemented. In addition, an LED element employed in the display according to the present disclosure is advantageous in increasing a light-emitting area as compared to a conventional rod-type LED element in which a major-axis direction and a stacking direction are identical in structure, allows an area of a photoactive layer exposed to the surface to be greatly reduced while the light-emitting area is increased so that efficiency degradation due to surface defects can be prevented or minimized, and can minimize the situation in which electron-hole recombination efficiency is lowered due to an electron-hole velocity imbalance and thus light emission efficiency is lowered, thereby implementing a display having a higher luminance.

While the embodiments of the present disclosure have been described above, the present disclosure is not limited to the embodiments presented herein. One skilled in the art may easily suggest other embodiments due to addition, modification, deletion, and the like of components within the scope and spirit of the present disclosure, and the addition, modification, deletion, and the like of the components fall within the scope and spirit of the present disclosure.

What is claimed is:

1. A direct-current-drivable full-color light-emitting diode (LED) display, the full-color LED display comprising:
a lower electrode line part including one or more first electrodes and having a plurality of sub-pixel sites formed on main surfaces of the first electrodes;
an alignment guide part configured to cover at least a main surface portion of each of the first electrodes corresponding to each of the sub-pixel sites and including two or more holes each passing through a portion corresponding to each of the sub-pixel sites so as to have a first shape;
a plurality of LED structures, each of which emits light of substantially the same color, includes a first conductive semiconductor layer, a photoactive layer, and a second conductive semiconductor layer, which are stacked in a first direction, and includes a first face and a second face facing each other in the first direction, wherein a shape of the second face and a shape of the first face, which is the first shape, are congruent with each other, but the shape of the first face and the shape of the second face have an asymmetric shape in which a symmetrical axis does not exist, and a second face side end portion of each of the LED structures is inserted into the hole of the alignment guide part such that the second face of each of the LED structures is brought into contact with the main surface of each of the first electrodes, and aligned on the first electrode;
an upper electrode line part including one or more second electrodes disposed on the plurality of aligned LED structures; and
a color conversion part patterned on main surfaces of the second electrodes corresponding to the sub-pixel sites so that the sub-pixel sites respectively become sub-pixel sites each expressing any one of a blue color, a green color, and a red color.

2. The full-color LED display of claim 1, wherein a shape of each of the remaining faces of the LED structure except for the first face and the second face is different from the shape of at least one of the first face and the second face.

3. The full-color LED display of claim 1, wherein
each of the first face and the second face has an area of 0.20 μm² to 100 μm², and
a thickness that is a vertical distance between the first face and the second face is in a range of 0.3 μm to 3.5 μm.

4. The full-color LED display of claim 1, wherein
the first conductive semiconductor layer is an n-type Group III-nitride semiconductor layer, and
an electron delay layer is further included below the first conductive semiconductor layer so that the number of electrons and the number of holes recombined in the photoactive layer are balanced.

5. The full-color LED display of claim 1, wherein
the first conductive semiconductor layer is an n-type Group III-nitride semiconductor layer,
the second conductive semiconductor layer is a p-type Group III-nitride semiconductor layer, and
the full-color LED display further includes
at least one functional film of a hole pushing film configured to cover exposed side surfaces of the second conductive semiconductor layer, or the exposed side surfaces of the second conductive semiconductor layer and exposed side surfaces of at least a portion of the photoactive layer, and move holes on the exposed side surface toward a center, and
an electron pushing film configured to cover exposed side surfaces of the first conductive semiconductor layer and move electrons on the exposed side surface toward a center.

6. The full-color LED display of claim 1, wherein the hole is formed in a portion of the alignment guide part corresponding to the main surface of the first electrode.

7. The full-color LED display of claim 1, wherein an area of the hole provided in the alignment guide part is formed to be 1.01 to 1.50 times larger than an area of the second face of each of the LED structures.

8. The full-color LED display of claim 1, wherein
in the lower electrode line part, a plurality of first electrodes are formed to be spaced apart from each other by a predetermined interval in a main surface direction,
each of the sub-pixel sites is formed on at least two adjacent first electrodes,
each of the LED structures is a rod-type LED structure elongated in a second direction perpendicular to the first direction with an aspect ratio of a major axis and a minor axis of 2:1 or more in each of the first face and the second face,
the hole passes through the alignment guide part such that a portion of the hole corresponds to the main surface of one of the two adjacent first electrodes and a portion of the remaining portion of the hole corresponds to the main surface of the remaining first electrode, so that a front-end second face portion and a rear-end second surface portion of the rod-type LED structure are respectively disposed on the main surfaces of the two adjacent first electrodes, and
the second face side end portion of each of the plurality of LED structures is inserted into the hole of the alignment guide part and aligned on the first electrode.

9. The full-color LED display of claim 1, wherein the light color is blue, white, or ultraviolet (UV)

10. A direct-current-drivable full-color light-emitting diode (LED) display, the full-color LED display comprising:
a lower electrode line part including one or more first electrodes and having a plurality of sub-pixel sites formed on main surfaces of the first electrodes;
an alignment guide part configured to cover at least a main surface portion of each of the first electrodes corresponding to each of the sub-pixel sites and including two or more holes each passing through a portion corresponding to each of the sub-pixel sites so as to have a first shape;
a plurality of LED structures, each of which includes a first conductive semiconductor layer, a photoactive layer, and a second conductive semiconductor layer, which are stacked in a first direction, includes a first face and a second face facing each other in the first direction, and includes a blue LED structure, a green LED structure, and a red LED structure, each of which has a shape in which a shape of the second face and a shape of the first face, which is the first shape, are congruent with each other but the shape of the first face and the shape of the second face have an asymmetric shape in which a symmetrical axis does not exist, wherein each of the LED structures is disposed in each of the sub-pixel sites so as to have substantially the same color of light, a second face side end portion of each of the LED structures is inserted into the hole of the alignment guide part such that the second face of each of the LED structures is brought into contact with the main surface of each of the first electrodes and aligned on the first electrode; and
an upper electrode line part including one or more second electrodes disposed on the plurality of aligned LED structures.

11. The full-color LED display of claim 10, wherein a shape of each of the remaining faces of the LED structure except for the first face and the second face is different from the shape of at least one of the first face and the second face.

12. The full-color LED display of claim 10, wherein
each of the first face and the second face has an area of 0.20 μm² to 100 μm², and
a thickness that is a vertical distance between the first face and the second face is in a range of 0.3 μm to 3.5 μm.

13. The full-color LED display of claim 10, wherein the hole is formed in a portion of the alignment guide part corresponding to the main surface of the first electrode.

14. The full-color LED display of claim 10, wherein an area of the hole provided in the alignment guide part is formed to be 1.01 to 1.50 times larger than an area of the second face of each of the LED structures.

15. The full-color LED display of claim 10, wherein
in the lower electrode line part, a plurality of first electrodes are formed to be spaced apart from each other by a predetermined interval in a main surface direction,
each of the sub-pixel sites is formed on at least two adjacent first electrodes,
each of the LED structures is a rod-type LED structure elongated in a second direction perpendicular to the first direction with an aspect ratio of a major axis and a minor axis of 2:1 or more in each of the first face and the second face,
the hole passes through the alignment guide part such that a portion of the hole corresponds to the main surface of one of the two adjacent first electrodes and a portion of the remaining portion of the hole corresponds to the main surface of the remaining first electrode, so that a front-end second face portion and a rear-end second surface portion of the rod-type LED structure are respectively disposed on the main surfaces of the two adjacent first electrodes, and
the second face side end portion of each of the plurality of LED structures is inserted into the hole of the alignment guide part and aligned on the first electrode.

16. A method of manufacturing a direct-current-drivable full-color light-emitting diode (LED) display, the method comprising:
operation (1) of preparing a lower electrode line part including one or more first electrodes and having a plurality of sub-pixel sites formed on main surfaces of the first electrodes;
operation (2) of forming an alignment guide part, which is configured to cover at least a main surface portion of each of the first electrodes corresponding to each of the sub-pixel sites and includes two or more holes each passing through a portion corresponding to each of the sub-pixel sites so as to have a first shape, on the lower electrode line part;
operation (3) of printing an ink composition for a printing apparatus, which includes a plurality of LED structures, each of which emits light of substantially the same color, includes a first conductive semiconductor layer, a photoactive layer, and a second conductive semiconductor layer, which are stacked in a first direction, and includes a first face and a second face facing each other in the first direction, wherein a shape of the second face and a shape of the first face, which is the first shape, are congruent with each other, but the shape of the first face and the shape of the second face have an asymmetric shape in which a symmetrical axis does not exist, on a region of the alignment guide part corresponding to each of the sub-pixel sites;
operation (4) of aligning the plurality of LED structures on the main surfaces of the first electrodes by inserting a second face side end portion of each of the LED structures placed on the alignment guide part into the hole of the alignment guide part;
operation (5) of forming an upper electrode line part including one or more second electrodes on the plurality of aligned LED structures so as to be in contact with the first face of the LED structure; and
operation (6) of patterning a color conversion part on the second electrode corresponding to the sub-pixel site so that the sub-pixel sites become sub-pixel sites each expressing any one of a blue color, a green color, and a red color in each of the plurality of sub-pixel sites.

17. The method of claim 16, wherein the aligning of the plurality of LED structures includes a process of radiating a sound wave one time or multiple times.

18. The method of claim 16, wherein a linker for chemical bonding is provided on any one or more of the second face of the LED structure, an inner surface of the hole, and a bottom surface of the hole, so that each of the plurality of LED structures aligned by being inserted into the hole is not separated from the hole.

19. The method of claim 16, wherein
each of the LED structures is a rod-type LED structure elongated in a second direction perpendicular to the first direction with an aspect ratio of a major axis and a minor axis of 2:1 or more in each of the first face and the second face,
in the lower electrode line part, a plurality of first electrodes are formed to be spaced apart from each other by a predetermined interval in a main surface direction,
each of the sub-pixel sites is formed on at least two adjacent first electrodes,
the hole is formed to pass through the alignment guide part such that a portion of the hole corresponds to the main surface of one of the two adjacent first electrodes and a portion of the remaining portion of the hole corresponds to the main surface of the remaining first electrode, so that a front-end second face portion and a rear-end second surface portion of the rod-type LED structure are respectively disposed on the main surfaces of the two adjacent first electrodes, and
the plurality of LED structures printed on the alignment guide part are aligned so that the second face side end portion is inserted into the hole by applying different power to the adjacent first electrodes.

20. The method of claim 16, further comprising:
after the plurality of LED structures are aligned on the first electrode,
heat-treating for improving electrical contact between the second face of the LED structure and the first electrode; and
depositing an insulating material to fill a space between each LED structure and the hole into which the LED structure is inserted and to planarize a space between the plurality of aligned LED structures.

21. A method of manufacturing a direct-current-drivable full-color light-emitting diode (LED) display, the method comprising:
operation (I) of preparing a lower electrode line part including one or more first electrodes and having a plurality of sub-pixel sites formed on main surfaces of the first electrodes;
operation (II) of forming an alignment guide part, which is configured to cover at least a main surface portion of each of the first electrodes corresponding to each of the sub-pixel sites and includes two or more holes each passing through a portion corresponding to each of the sub-pixel sites so as to have a first shape, on the lower electrode line part;
operation (III) printing a blue LED structure ink composition, a green LED structure ink composition, and a red LED structure ink composition each including a plurality of LED structures for each light color, each of which includes a first conductive semiconductor layer, a photoactive layer, and a second conductive semiconductor layer, which are stacked in a first direction, and includes a first face and a second face facing each other in the first direction, wherein a shape of the second face and a shape of the first face, which is the first shape, are congruent with each other, but the shape of the first face and the shape of the second face have an asymmetric shape in which a symmetrical axis does not exist, and the ink compositions are printed on a region of the alignment guide part corresponding to each of the sub-pixel sites so that each of the plurality of sub-pixel sites independently expresses any one color;
operation (IV) of aligning the plurality of LED structures by inserting a second face side end portion of each of the LED structures placed on the alignment guide part into the hole of the alignment guide part; and
operation (V) of forming an upper electrode line part including one or more second electrodes on the plurality of aligned LED structures so as to be in contact with the first face of the LED structure.

22. The method of claim 21, wherein the aligning of the plurality of LED structures includes a process of radiating a sound wave one time or multiple times.

23. The method of claim 21, wherein a linker for chemical bonding is provided on any one or more of the second face of the LED structure, an inner surface of the hole, and a bottom surface of the hole, so that each of the plurality of LED structures aligned by being inserted into the hole is not separated from the hole.

24. The method of claim 21, wherein
each of the LED structures is a rod-type LED structure elongated in a second direction perpendicular to the first direction with an aspect ratio of a major axis and a minor axis of 2:1 or more in each of the first face and the second face,
in the lower electrode line part, a plurality of first electrodes are formed to be spaced apart from each other by a predetermined interval in a main surface direction,
each of the sub-pixel sites is formed on at least two adjacent first electrodes,
the hole is formed to pass through the alignment guide part such that a portion of the hole corresponds to the main surface of one of the two adjacent first electrodes and a portion of the remaining portion of the hole corresponds to the main surface of the remaining first electrode, so that a front-end second face portion and a rear-end second surface portion of the rod-type LED structure are respectively disposed on the main surfaces of the two adjacent first electrodes, and
the plurality of LED structures printed on the alignment guide part are aligned so that the second face side end portion is inserted into the hole by applying different power to the adjacent first electrodes.

25. The method of claim 21, further comprising:
after the plurality of LED structures are aligned on the first electrode,
heat-treating for improving electrical contact between the second face of the LED structure and the first electrode; and
depositing an insulating material to fill a space between each LED structure and the hole into which the LED structure is inserted and to planarize a space between the plurality of aligned LED structures.
